(19) United States
(12) Patent Application Publication
(10) Pub. No.: US 2004/0189502 A1
(43) Pub. Date: Sep. 30, 2004

(54) Multi-level pulse width modulation in digital system

(76) Inventor: Ying Lau Lee, Hong Kong (CN)

Correspondence Address: WEINGARTEN, SCHURGIN, GAGNEBIN & LEBOVICI LLP, TEN POST OFFICE SQUARE, BOSTON, MA, 02109, US

(21) Appl. No.: 10/819,573

(22) Filed: Apr. 7, 2004

Related U.S. Application Data
(63) Continuation-in-part of application No. 10/678,614, filed on Oct. 3, 2003.
(60) Provisional application No. 60/451,394, filed on Mar. 4, 2003.
(60) Provisional application No. 60/518,633, filed on Nov. 12, 2003.

(51) Int. Cl. H03M 1/76; H03M 1/82

(52) U.S. Cl. 341/152; 341/148

(57) ABSTRACT

A multi-level pulse width modulation (multi-level PWM) technique uses multiple voltage levels and/or multiple output channels to obtain improved resolution (also referred to as dynamic range) over ordinary PWM-based digital systems, in particular digital audio systems. A digital audio signal is converted to either (1) an N-level PWM signal which is output to a single channel including a filter and loudspeaker, (2) N components of an N-level PWM signal output to N corresponding channels, (3) some number of multi-level signals output to multiple channels or (4) some number of PWM signals output to multiple channels. The digital audio signal can also be divided into different frequency bands to be processed separately and output to different sets of loudspeakers, wherein fewer low frequency loudspeakers can be used than high frequency loudspeakers to produce equal effective resolution for the output of all frequency bands. The multi-level PWM technique can also be adapted to control the output of other types of PWM-based systems when greater resolution is desired.

### CROSS REFERENCE TO RELATED APPLICATIONS

This application claims priority under 35 U.S.C. §120 of U.S. patent application Ser. No. 10/678,614 filed Oct. 3, 2003, which claims priority under 35 U.S.C. §119(e) of U.S. Provisional Patent Application No. 60/451,394 filed Mar. 4, 2003. This application also claims priority under 35 U.S.C. §119(e) of U.S. Provisional Patent Application No. 60/518,633 filed Nov. 12, 2003.

### STATEMENT REGARDING FEDERALLY SPONSORED RESEARCH OR DEVELOPMENT

--Not Applicable--

### BACKGROUND OF THE INVENTION

The invention relates to the field of digital systems employing pulse width modulation (PWM), and in particular to digital audio systems employing PWM to generate audio signals from corresponding digital signals.

The current trend in the audio field is for digital recording and retrieval of audio source material, rather than analog recording and retrieval as practiced for so long in the history of the field. As a result, digital audio amplifier systems suitable for direct processing of digital sources have been of great interest to the consumer electronics industry over the past few years. Digital audio amplifier systems eliminate the need for an intermediate digital-to-analog conversion, and thereby offer improved sound quality.

A typical prior art digital audio amplifier system for direct processing of a digital audio signal includes an interpolator stage which employs inter-sample estimating to up-sample the digitally-encoded audio stream to a rate several times the original sampling rate; a pulse width modulation (PWM) converter stage that converts digital samples to fixed-amplitude pulses with pulse widths corresponding to sample values; and a power-switching stage controlled by the PWM pulse signal. The output of the power-switching stage is fed to a low-pass filter such as an inductor-capacitor (LC) filter, and the output of the filter is fed to one or more loudspeakers.

The purpose of the interpolator circuit is to increase the frequencies of sampling-induced frequency components (such as aliasing components) to facilitate attenuation of such components by the low-pass filter and thereby render them substantially inaudible at the loudspeaker. However, there are practical limits to the resolution or dynamic range of the amplifier that are reached at high sampling frequencies. These limits arise from the limited switching speed of the power output switches. For example, for a digital signal having 10-bit quantization and a 48 KHz sampling rate up-sampled by a factor of 8, faithful reproduction would require switching speeds on the order of 2-3 ns. This is generally not feasible for present high-power switching components, and in any event might result in an unfavorable cost/performance tradeoff.

Accordingly, it is also common to include a noise shaper circuit in current digital audio systems to convert the high-resolution data from the interpolator stage to lower-resolution data. For example, a 16-bit quantized digital signal might be reduced to 6 to 8 bits of quantization at the higher up-sampled rate, to better match the characteristics of the digital signal with the switching speed of the power output switches.

The up-sampling of the digital signal tends to offset some of the loss of resolution from the noise shaper. For example, up-sampling by a factor of 8 can theoretically offset a 3-bit loss of resolution from the noise shaper. However, the overall resolution of the digital audio system is still undesirably limited, especially in comparison to the 16-bit resolution of modern compact disc (CD) systems. It would be desirable to provide for greater resolution in digital audio systems without requiring very-high-speed switching devices.

### BRIEF SUMMARY OF THE INVENTION

In accordance with the present invention, methods and apparatus providing multi-level pulse width modulation (multi-level PWM) are disclosed. An input signal is converted into an N-level PWM signal which conceptually is a composite signal consisting of the sum of a fixed amplitude PWM pulse with variable pulse width Tw within a sampling cycle and a pulse with width equal to the maximum pulse width Twmax of the PWM pulse within the sampling cycle and amplitude equal to n times the amplitude of the fixed-amplitude PWM pulse, where n can be any number from 0 to N-1 and Twmin is the minimum width of the said PWM pulse within the sampling cycle such that the value of (Tw+n*Twmax)/Twmin for the sampling cycle equals the value of the data sample of the input signal in that sampling cycle. It can be seen that a system employing N-level PWM has N times the resolution of a corresponding system employing PWM. It should be noted that the term PWM signal or pulse referred herein should be taken in a broad sense to mean any signal which utilizes the width of a pulse or the sum of the widths of a group of pulses in a sampling cycle to represent the value of the data sample in that sampling cycle. In the case of a PWM signal composing of a group of pulses in a sampling cycle, the aforesaid variable pulse width Tw within a sampling cycle shall mean the sum of the width of the pulses in the group in the sampling cycle.

The multi-level PWM can be applied to digital amplification in high fidelity audio systems to address the limitation in resolution of existing PWM-based digital audio system. The multi-level PWM can also be adapted to control the output of other types of systems with similar improvement in resolution.

In general, apparatus is disclosed for controlling switching circuitry being operative to generate an analog output from a digital signal, the digital signal carrying multi-bit values at a sampling rate. The analog output may be audio sound outputs or other types of outputs.

The digital signal also includes first and second digital sub-signals carrying, respectively, the least-significant and most-significant components of the multi-bit values carried by the digital signal.

The apparatus includes switch control circuitry that generates a set of control signals to control the electrical outputs of the switching circuitry. The control signals collectively include a pulse width modulated signal based on the first digital sub-signal and multi-channel and/or multi-level control signals based on the second digital sub-signal. By including the multi-channel and/or multi-level control, the apparatus can provide additional resolution in the analog output than provided by apparatus that employs only pulse width modulation. The resolution increases by a factor of n, where n is equal to the aggregate total of the number of different levels available in each channel.

Four embodiments of the apparatus are shown. In a first embodiment, the analog output is generated from a multi-level electrical signal including a pulse width modulated component and a multi-level component. The switching circuitry includes a number of switches each providing one of the levels of the multi-level electrical signal in response to assertion of a corresponding control signal. A PWM converter generates a pulse width modulated signal and a maximum-width-pulse signal, the pulse width modulated signal being based on the first digital sub-signal, the maximum-width-pulse signal establishing the maximum permissible pulse duration in a sampling cycle for the pulse width modulated signal. The switch control circuitry includes a level selector that asserts each control signal based on the PWM converter's signals and the second digital sub-signal. In this embodiment, respective sources of all the levels of the multiple levels of the electrical signal are required, such as a set of power supplies each providing a different voltage level.

In a second embodiment, the analog output is generated by additively combining a plurality of analog component outputs generated from corresponding electrical signals from separate channels (the term “channel” being used in a generic sense independent of other channelization that may occur in the system, such as traditional stereo or quadraphonic separation). In the case of an audio analog output, the analog component outputs are audio component outputs from separate loudspeakers, which are additively combined in a transmission medium such as air. The switching circuitry includes a number of switches that each generates a predetermined level on the electrical signal of the channel in response to a corresponding control signal. A PWM converter generates a pulse width modulated signal and a maximum-width-pulse signal, the pulse width modulated signal being based on the first digital sub-signal, the maximum-width-pulse signal establishing the maximum permissible pulse duration in a sampling cycle for the pulse width modulated signal. The switch control circuitry includes an encoder that asserts different numbers of the control signals based on the value of the second digital sub-signal. In one channel the control signal for the switching circuitry consists of the pulse width modulated signal. In the other channels, the control signals consist of the control signals from the encoder and the maximum-width-pulse signal from the PWM converter. In this embodiment, only a single level is required to generate each electrical signal, and thus this embodiment can operate from a single power supply.

The third embodiment employs both multi-level electrical signals and multiple channels whose outputs are additively combined. Additionally, filters are utilized to separate the digital audio signal into separate frequency bands, so that the digital-to-analog circuitry for each band can be optimized. A higher frequency band can achieve a certain resolution using the multiple-channel approach, whereas fewer channels (e.g., only one) are needed to obtain the same resolution in lower frequency bands.

The fourth embodiment employs an additional channel whose switching circuitry is controlled to have its output swing between an equal magnitude of positive and negative voltage level by a pulse width modulated signal based on a first digital sub-signal (such as generated in the third embodiment). The outputs from the switching circuitry of the other channels are controlled to swing between an equal magnitude of higher positive and negative voltage level by control signals based on a second digital sub-signal (such as generated in the third embodiment). The analog component outputs generated from corresponding channels are then additively combined to produce the analog output similar to the third embodiment.

Other aspects, features, and advantages of the present invention will be apparent from the Detailed Description of the Invention that follows.

### BRIEF DESCRIPTION OF THE SEVERAL VIEWS OF THE DRAWING

The invention will be more fully understood by reference to the following Detailed Description of the Invention in conjunction with the Drawing, of which:

FIG. 1 is a block schematic diagram showing the principal components of a typical prior art PWM based digital audio power amplifier;

FIG. 2 is a block schematic diagram of a digital audio system employing multi-level PWM in a first fashion in accordance the present invention;

FIG. 3 is a timing diagram illustrating the operation of the digital audio system of FIG. 2;

FIG. 4 is a block schematic diagram of a digital audio system employing multi-level PWM in a second fashion in accordance with the present invention;

FIG. 5 (consisting of FIGS. 5a and 5b) is a block schematic diagram of a digital audio system employing multi-level PWM in a third fashion in accordance with the present invention;

FIG. 6 is a timing diagram illustrating the operation of the digital audio system of FIG. 5;

FIG. 7 (consisting of FIGS. 7a and 7b) is a block schematic diagram of a digital audio system similar to the system of FIG. 5 employing multi-level PWM in a fourth fashion in accordance with the present invention; and

FIG. 8 is a timing diagram illustrating the operation of the switching stages of the digital audio system of FIG. 7.

### DETAILED DESCRIPTION OF THE INVENTION

The disclosures of U.S. Provisional Patent Application No. 60/451,394 filed Mar. 4, 2003, U.S. Utility patent application Ser. No. 10/678,614 filed Oct. 3, 2003 and U.S. Provisional Patent Application No.60/518,633 filed Nov. 12, 2003 are hereby incorporated by reference.

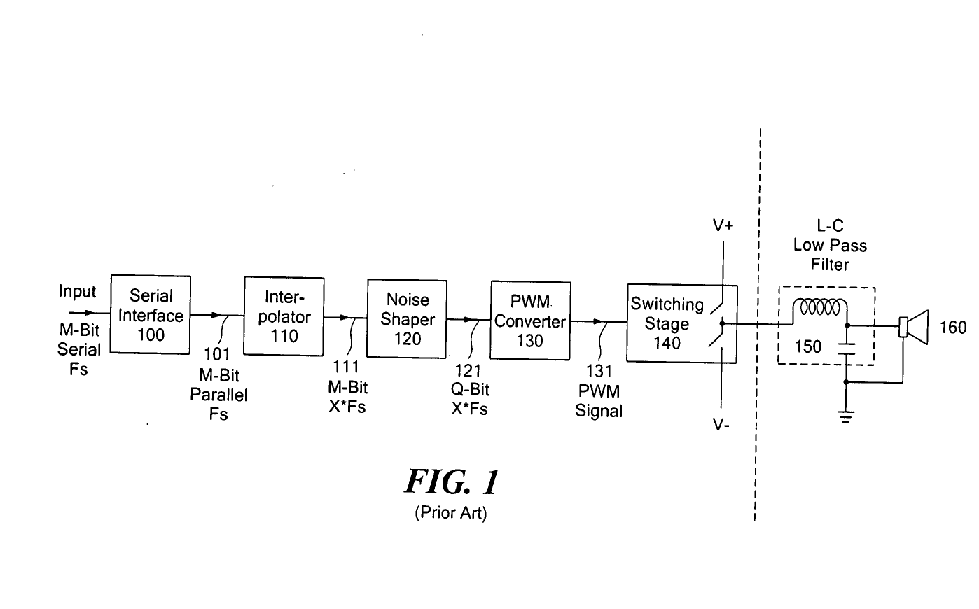

A typical prior art digital audio amplifier system for direct processing of a digital audio signal is shown in FIG. 1. The amplifier includes a serial interface 100, interpolator 110, noise shaper 120, pulse width modulation (PWM) converter 130, and a switching stage 140. The output of the switching stage 140 feeds an inductor-capacitor (L-C) low-pass filter 150 which in turn feeds a loudspeaker 160. The serial interface 100 converts an M-bit serial digital input data stream at a sampling rate Fs into an M-bit parallel data stream 101 at the same sampling rate. The interpolator stage 110 up-samples the M-bit parallel data 101 at a rate X times the original sampling rate of Fs, i.e. X*Fs (typically over 300 KHz), by estimating the required intermediate values between two consecutive data samples. This enables attenuation of the sampling frequency components by the low pass filter 150 to render such frequency components substantially inaudible at the loudspeaker 160.

The noise shaper stage 120 converts the high resolution data signal 111 from the interpolator 110 to a coarse-quantized data signal 121 with reduced resolution of Q bits (e.g. 6-8 bits) at the sampling rate of X*Fs to be compatible with the switching speed of the switching devices in the switching stage 140, as explained above. The PWM converter 130 converts the Q-bit coarse-quantized data signal 121 to a PWM signal 131. In one typical implementation, the PWM converter compares each input Q-bit data sample with the output of a counter clocked by a bit-clock running at X*(2^{Q})*Fs, which is typically the fastest clock in the system and defines the minimum pulse width of the PWM signal 131. The switching stage 140 typically consists of high speed power MOSFET switches in H-bridge configuration operated in the cut-off or saturation region. The switches are controlled by the PWM signal 131 to transfer power from a power supply (not shown) through the L-C low pass filter 150 to the loudspeaker 160.

The amplifier in FIG. 1 can be implemented digitally from the serial interface 100 through the switching stage 140 without requiring any intermediate digital to analog conversion, and theoretically has less noise and distortion and better performance than other approaches. As described above, the practical resolution or dynamic range of such an amplifier is limited by the switching speed of the power output switches in switching stage 140. For this reason, present PWM based audio power amplifiers generally employ some sort of noise shaping technique (represented in FIG. 1 by the noise shaper 120) to reduce the resolution of each sample of the output PWM signal. While this reduced resolution is more compatible with existing switching devices, it also undesirably limits performance.

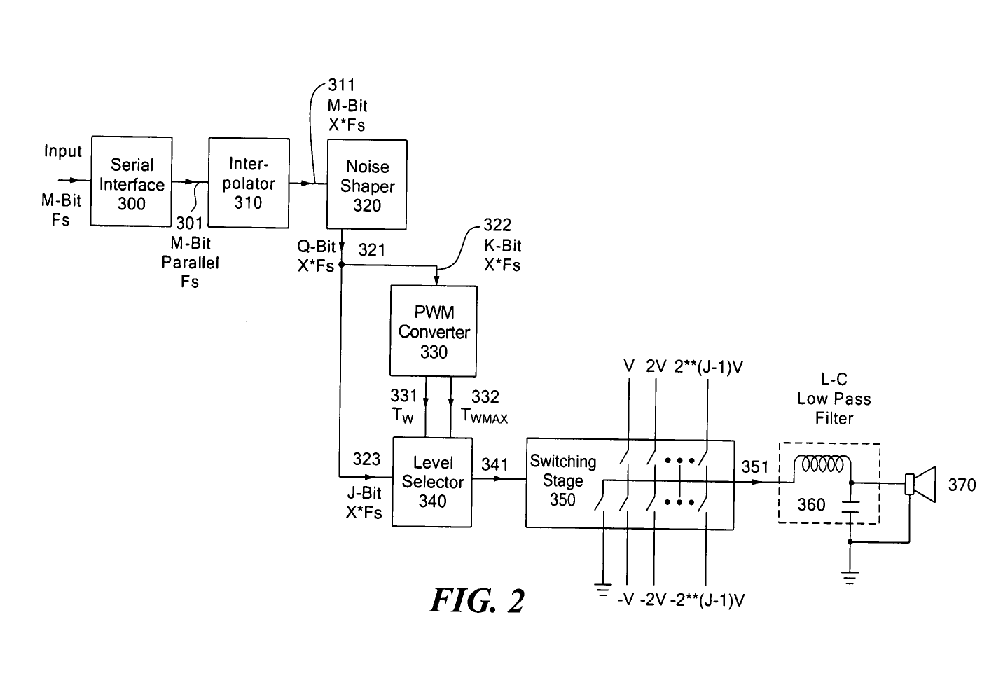

FIG. 2 shows a first embodiment of a multi-level PWM technique for obtaining improved performance over digital amplifiers of the type depicted in FIG. 1. The serial interface 300 and interpolator 310 operate in the same manner as their counterparts in the amplifier of FIG. 1 to produce an M-bit up-sampled data stream 311 which is assumed to be unsigned (a signed data can be converted to an unsigned data by adding an offset to it). A noise shaper 320 converts the M-bit up-sampled data stream 311 to a coarse-quantized data stream 321 with reduced resolution of Q bits at the up-sampled rate of X*Fs. Each Q-bit data sample is divided into two data samples, one sample having the K least significant bits and one sample having the J most significant bits, where Q=J+K. The streams of K-bit samples and J-bit samples respectively form sub-signals 322 and 323 of the Q-bit signal 321.

A PWM converter 330 converts the K-bit data stream 322 into a PWM signal Tw 331. As shown, the PWM converter 330 also generates a signal Twmax 332 having a fixed pulse width equal to the maximum pulse width of Tw 331 in the sampling cycle, which is described in more detail below.

The signals Tw 331 and Twmax 332 are provided to a level selector 340 along with the J-bit data stream 323. These signals are used by the level selector 340 to control a set of switches in an output switching stage 350 to switch among 2^{J}+1 voltage levels (including the zero voltage level) to generate a multi-level PWM signal 351. The multi-level PWM signal 351 is supplied to a low-pass filter 360 which drives a loudspeaker 370. The voltage levels selectable by the switching output stage 350 can have positive or negative polarity as shown and have amplitudes equal to respective multiples of a predetermined fixed reference voltage level “V”.

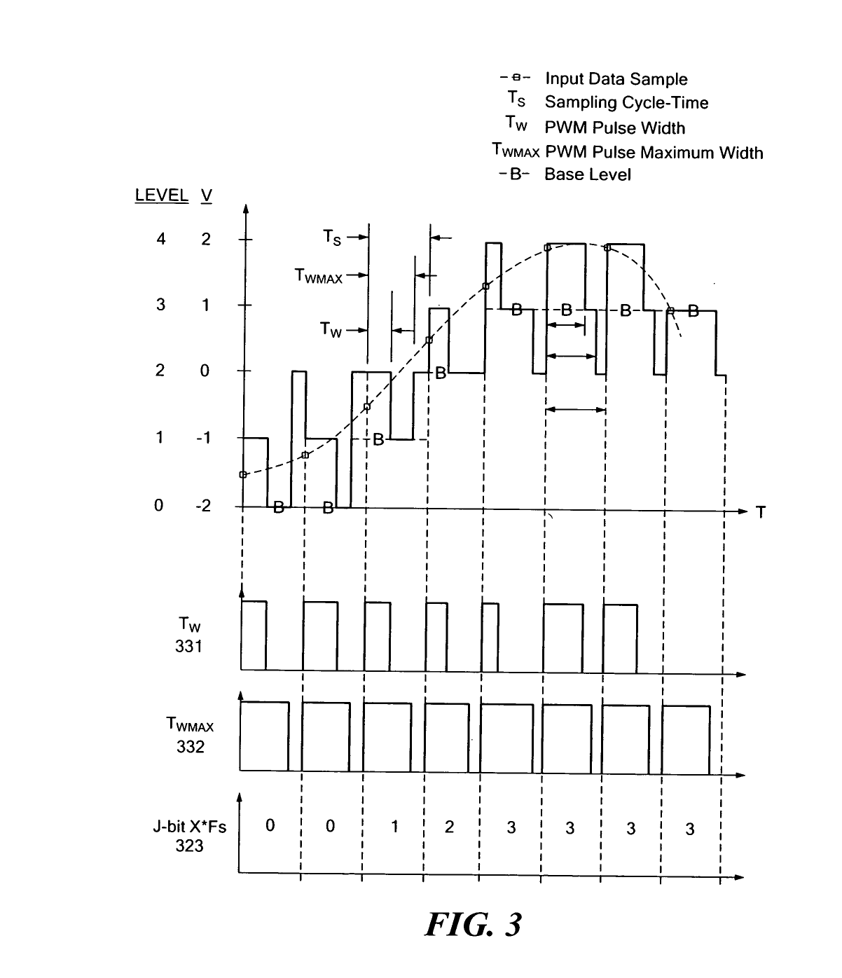

The level selector 340 controls the set of switches in the output switching stage 350 to switch among the levels in a manner tending to minimize the power required to operate the amplifier and the DC current flowing through the loudspeaker 370. In particular, during each sampling cycle the level selector 340 generates control signal 341 to select among the output voltages provided by the switching stage 350. The generation of the control signals occurs in the manner described below, which is illustrated for the special case of J=2 in FIG. 3:

1. During the portion of each sampling cycle as established by the variable-width pulse of Tw 331, a voltage is selected that is one level higher (more positive) than a base voltage level for the cycle as established by the value of the J-bit signal 323 (described below). Thus, if the base voltage level is +2V, the level +3V is selected during that portion of the cycle.

2. During the other portion of the cycle, the base voltage level for the cycle is selected. As indicated above, the base voltage level is established by the J-bit value. A binary value of zero corresponds to the lowest (i.e. most negative) voltage level (i.e., −2^{(J-1)}V), and successively greater binary values correspond to successively higher voltages. This portion of the cycle lasts until the end of the maximum pulse duration as established by the signal Twmax 332.

3. During the remainder portion of each sampling cycle that extends beyond the maximum pulse duration as established by Twmax, the zero voltage level is selected. The zero value is also selected in the absence of the input signal 301.

It can be seen that a supply of P different voltages is needed under the scheme of FIG. 2 to produce P-level PWM signals. This requires the use of a multi-output power supply or a set of single-output power supplies each providing a different output voltage.

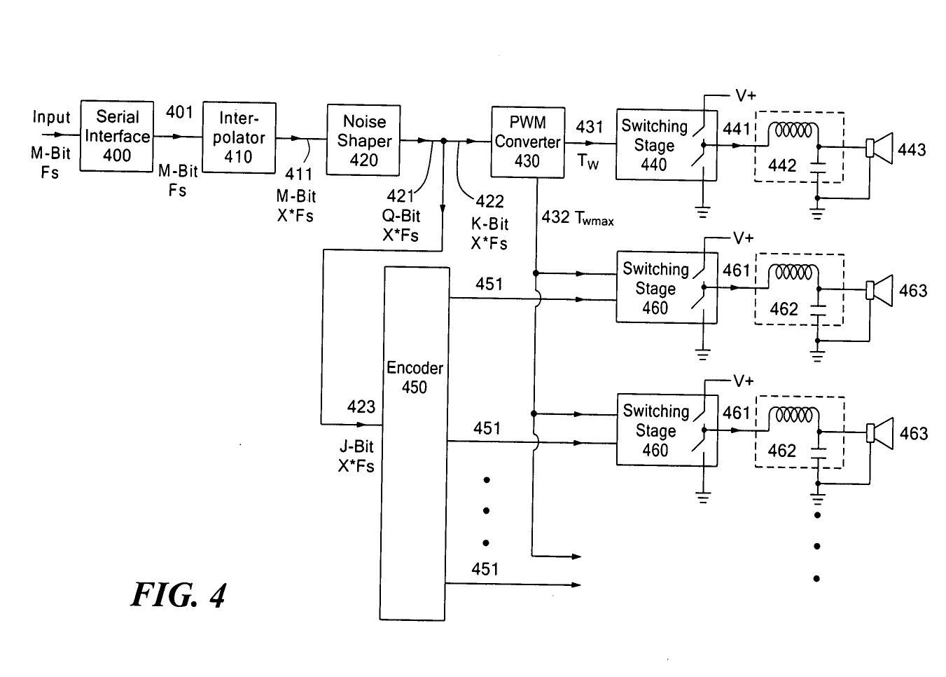

FIG. 4 shows a second embodiment of a multi-level PWM technique that requires only one supply voltage. The operations of the serial interface 400, interpolator 410, noise shaper 420, and PWM converter 430 are the same as the corresponding elements in the amplifier of FIG. 2. The M-bit data stream 411 is assumed to be unsigned (a signed data can be converted to an unsigned data by adding an offset to it). An encoder 450 converts the J-bit values 423 to a pattern of “ON” values on 2^{J}−l control lines 451, such that the total number of control lines 451 turned on at any given time corresponds to the binary number represented by the J-bit data 423 at that time. For the above case of J=2, this encoding could be realized as follows:

| | # of control |
|---|---|
| J | lines ON |
| 00 | 0 |
| 01 | 1 |
| 10 | 2 |
| 11 | 3 |

The control lines 451 and the Twmax signal 432 from the PWM converter 430 control each of a set of switches 460 to switch between a single voltage level V and the zero voltage level, such that a maximum-width pulse 461 (width equal to Twmax 432) is outputted to each low pass filter 462 for which the corresponding control line 451 is ON in a sampling cycle. The filtered signal is provided to the corresponding loudspeaker 463.

Additionally, the Tw signal 431 from the PWM converter 430 is provided to a set of switch 440 that also switches between the voltage level V and the zero voltage level. In this case, a variable-width pulse stream at the sampling rate of X*Fs is outputted to a low pass filter 442 and the filtered signal is provided to a loudspeaker 443.

The separate acoustic signals from the speakers 443 and 463 are mixed additively in the sound-carrying medium, typically air, to produce the same acoustic effect as when a single low pass filter and loudspeaker are used to output a multi-level PWM signal such as described above with reference to FIGS. 2 and 3. Thus, the separate signals constitute component signals of the overall acoustic audio signal. It can be seen that P output channels are required to achieve the same effect as the one channel technique of FIGS. 2 and 3 producing P-level PWM signals. Alternatively, the PWM channel containing the PWM converter 430 can work in the same corresponding manner as any of the prior art digital amplifiers to generate an output from a PWM signal. In such case, the output of the PWM channel may have to be equalized with those of the other channels.

In addition to the amplifiers of FIGS. 2 and 4, amplifiers using a hybrid approach can also be constructed. That is, a multi-level PWM amplifier can be made using multiple supply voltages and multiple channels. An example is presented below in connection with the use of frequency division (or crossover separation) to make more efficient use of multiple loudspeakers.

Often, any single loudspeaker is not able to faithfully reproduce the whole spectrum of audio frequencies. Some types of loudspeakers are better at reproducing lower frequencies, while other types of loudspeakers are better at reproducing higher frequencies. Traditionally, high fidelity audio systems employ analog band filters or crossover networks to divide the amplified audio signal into multiple signals in different frequency bands. The different signals are fed to different loudspeakers, where each loudspeaker is tailored for reproducing sounds of the frequency band of the signal it receives. For digital audio systems employing a single-output amplifier such as the amplifier of FIG. 2, it may be practical for the loudspeaker system to include a number of loudspeakers and a crossover network. However, for systems employing a multiple-output technique such as shown in FIG. 4, the number of loudspeakers that is required may be impracticably high, especially the large loudspeakers generally required for the low frequency band.

To address this issue, it is noted that a low frequency signal can be sampled at a lower rate than a high frequency signal to produce the same resolution. For example, sampling a 3 KHz signal at 96 KHz and a 12 KHz signal at 384 KHz provide the same resolution. Also, sampling a 3 KHz signal at 384 KHz shall, theoretically, provide 4 times greater resolution than sampling a 12 KHz signal at the same 384 KHz. Hence, if the digital signal is divided into a high frequency band and a low frequency band with an appropriate crossover frequency, such as 3 KHz, and the two signals are processed separately but in the same way in an amplifier employing the multiple-output approach, the outputs of the low frequency band have about 4 times the resolution of the outputs of the high frequency band. As a result, one quarter of the number of loudspeakers or channels employed in the high frequency band can be employed in the low frequency band so that the outputs of both bands have the same effective resolution. Those skilled in the art will appreciate that the number of frequency bands may be different in different applications.

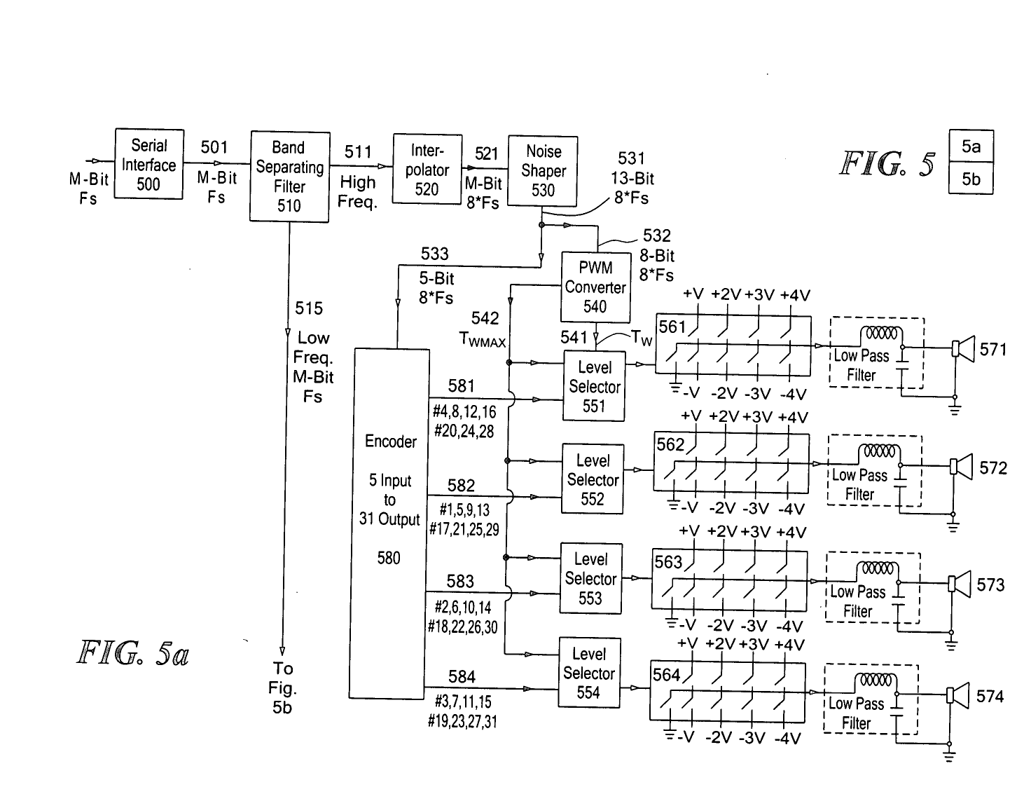

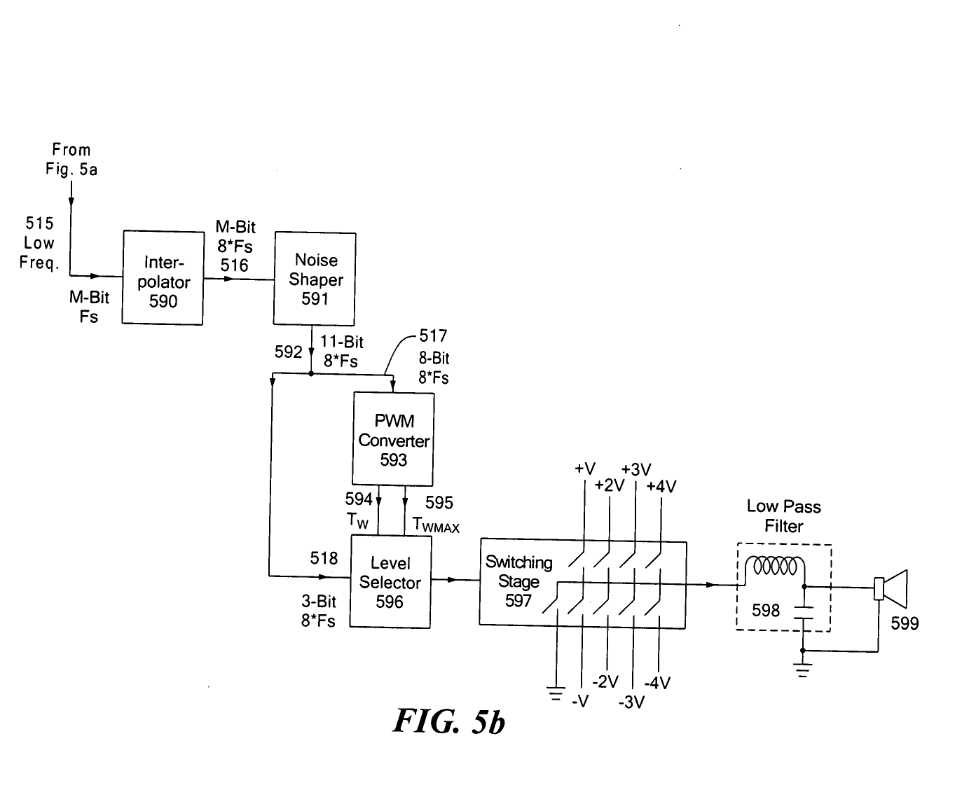

FIG. 5 shows an example of a system employing such frequency division, along with the multi-channel, multi-voltage hybrid approach mentioned above. The system of FIG. 5 employs a band-separating filter 510 to divide the M-bit parallel data signal 501 into a high frequency M-bit signal 511 and a low frequency M-bit signal 515. The crossover frequency of the band-separating filter 510 in this two-way frequency division is 3 KHz. The system employs four channels and 8 non-zero voltage levels for the high frequency M-bit signal 511, resulting in a resolution of 32 times (or 5 bits more) the resolution that can be provided by just employing PWM using similar-speed switching devices.

The low frequency M-bit signal 515 can be processed in the manner shown in FIG. 2 employing 8 nonzero voltage levels, i.e., using a single-output, multiple-voltage approach to achieve the same effective resolution as its high frequency counterpart as explained in above.

The high-frequency M-bit signal 511 is processed in the hybrid manner discussed above, i.e., using multiple channels as well as multiple voltages in each channel. The high frequency M-bit signal 511 which is assumed to be unsigned (a signed data can be converted to an unsigned data by adding an offset to it) goes through the interpolator 520 which up-samples the M-bit data 511 at a rate X times the original input sampling rate of Fs i.e. X*Fs to produce the M-bit data 521. In this example X=8. The noise shaper 530 converts the M-bit up-sampled data 521 to a coarse-quantized data 531 with reduced resolution of Q bits at the same sampling rate of 8*Fs. In this example Q=13. Each Q-bit data sample 531 is split into two data samples, one sample of J bits 533 (in this example J=5) and one sample of K bits 532 (in this example K=8) where Q=J+K. The J-bit sample 533 represents the most significant bits of the coarse-quantized Q-bit data sample 531 whereas the K-bit sample 532 represents the least significant bits of the coarse-quantized Q-bit data sample 531.

A PWM converter 540 converts the 8-bit data 532 directly to a PWM signal and outputs the PWM pulse with width Tw 541 and the maximum pulse width Twmax 542 of the PWM signal to the level selector 551.

An encoder 580 receives the 5-bit data signal 533 and uses this signal to control the states of 31 control lines in four groups 581, 582, 583 and 584. These control lines are shown as numbered from #1 to #31. Each of these control lines is turned ON whenever the binary number represented by the 5-bit data 533 is greater than or equal to the number associated with the control line. For example, if a 5-bit data value of ‘01000’ is provided to the encoder 580, control lines #1 to #8 are ON and the rest of the control lines are OFF. The PWM output signal Tw 541 and the 31 control lines from the encoder 580 together represent a 32-level PWM signal.

During each sampling cycle the level selector 552, 553 or 554 generates control signals to select among the 9 output voltage levels (including the zero voltage level) provided by the switching stage 562, 563 or 564 respectively. The selection of output voltage levels occurs in the manner described below:

1. During the portion of each sampling cycle established by the signal Twmax 542, the output voltage level or base voltage level for the cycle is selected according to the number of control lines that is ON in the group (582, 583 or 584 respectively) connected to the level selector. No control lines ON corresponds to the lowest voltage level (i.e., −4V), and successively greater number of control lines ON corresponds to successively higher voltages.

2. During the remainder portion of each sampling cycle that extends beyond the maximum pulse duration as established by Twmax, the zero voltage level is selected. The zero value is also selected in the absence of the input signal 511.

Level selector 551 differs from the other level selectors because it receives the signal Tw 541 in addition to control lines in group 581 from the encoder 580 and the signal Twmax 542. Level selector 551 thus operates in the same manner described above for level selector 340 of FIG. 2 with the number of control lines in group 581 ON corresponding to the value of the J-bit signal 323 of FIG. 2, i.e., no control line ON to level selector 551 corresponds to J-bit value equal to zero for the level selector 340. In particular, each cycle of the pulse signal outputted by the switching stage 561 has a variable-width portion that is one level higher than the other portion of the cycle as determined by the signal Tw 541. In contrast, the switching stages 562, 563 and 564 output only maximum-width pulses (width equal to Twmax 542).

As shown in FIG. 5, the control lines from the encoder 580 are grouped into four groups as follows:

1. Group 581 includes lines #4, #8, #12, #16, #20, #24, #28;

2. Group 582 includes lines #1, #5, #9, #13, #17, #21, #25, #29;

3. Group 583 includes lines #2, #6, #10, #14, #18, #22, #26, #30;

4. Group 584 includes lines #3, #7, #11, #15, #19, #23, #27, #31;

Those skilled in the art will appreciate that the number of control lines in a group and the way to group the control lines from the encoder 580 is a matter of choice as is appropriate for the specific system to which the present invention is put to use.

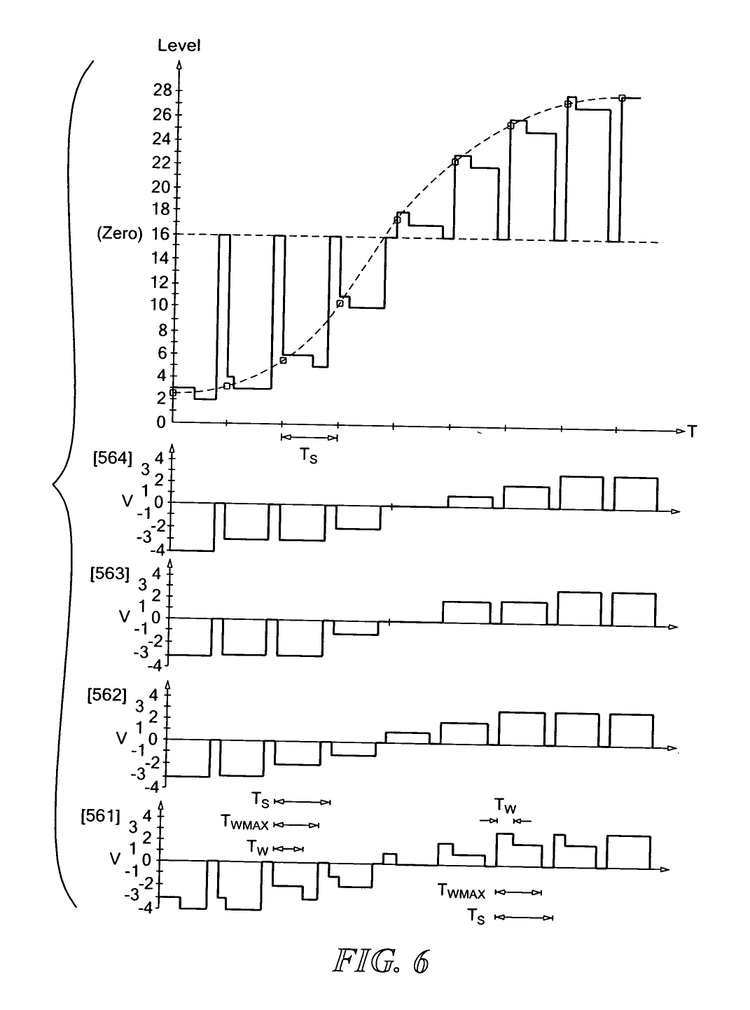

Because of the interleaved nature of the grouping of the control lines, each successively higher value of the 5-bit signal 533 results in increasing the base level in a successively different channel rather than increasing the base level in only one channel at a time. This helps to distribute power evenly among the different loudspeakers 571, 572, 573 and 574. This operation is explained in more detail with respect to FIG. 6 below.

FIG. 6 illustrates the output signals from the switching stages 561, 562, 563 and 564 to their corresponding L-C low pass filters of the high-frequency loudspeakers 571, 572, 573 and 574 of FIG. 5 for a particular sampled analog signal. The additive effect of the four channels is depicted as a pulse waveform superimposed on the analog signal. The incremental increasing of base level across the channels is shown. For example, in the second cycle, the base level is increased by one step for the channel containing switches 564. In the third cycle, the base level is increased in the channels containing switches 561 and 562, etc.

The system of FIG. 5 produces the same acoustic effect as though an equivalent 32-level PWM signal were provided to a single equivalent L-C low pass filter and loudspeaker. This is equivalent to 5 additional bits of resolution. With the 8-bit resolution of the signal from the noise shapers 530 and the 3-bit increase in resolution created by the interpolators 520, the overall system resolution is 5+8+3=16 bits. In general, using Y channels and a Z-voltage-level power supply to the full extent yield the equivalent of a (Y*Z)-level PWM signal.

It should be noted that it is desirable to equalize the respective outputs of the one-channel low-frequency band and the four-channel high-frequency band. This can be accomplished, for example, by making the four high frequency loudspeakers 571, 572, 573 and 574 with equal impedance and making the low frequency loudspeaker 599 with an impedance one quarter of that of each high frequency loudspeaker.

A variation of the multi-voltage and multi-channel scheme is to have a dedicated channel for the PWM signal so that the output of this PWM channel swings between a positive and negative voltage level instead of between two adjacent levels and become zero only if there is no input signal or during the remainder portion of each sampling cycle that extends beyond the maximum pulse duration as established by Twmax. This PWM channel is still count as single level although it has an extra zero level. Alternatively, the dedicated PWM channel can also work in the same corresponding manner as any of the prior art digital amplifiers to generate an output from a PWM signal. The other channels are multi-level just like those channels that contain the level selectors 552, 553 and 554 in FIG. 5. However, the output of the PWM channel has to be equalized with those of the other channels. This scheme has the advantage of being able to make use of the same prior art circuitry to handle the least significant K bits of the input signal and only has to add multi-level channels to handle the most significant J bits of the input signal. The disadvantage of this scheme is that it requires one more channel than the scheme of FIG. 5 for the same resolution.

Since all of the above schemes are based on unsigned data sample, therefore when the output of a channel is multi-level and swings between positive and negative voltage levels, the PWM pulse appears to be near the end of the sampling cycle when the output is negative. Usually the position of the PWM pulse within a sampling cycle is not significant but if it is important for a specific application, the logic of the level selector of the multiple voltage levels schemes needs the following changes to correct it. The PWM converter stage needs to output an extra Tx signal with pulse width equal to (Twmax−Tw) at the beginning of a sampling cycle. Whenever the value of the J-bit data input to the level selector or encoder in FIG. 2 or FIG. 5 falls below a threshold indicating a negative output level, the level selector that normally use the Tw signal uses the Tx signal instead to control the set of switches such that the voltage level outputted during Twmax but not during Tx is one voltage level higher than during Tx.

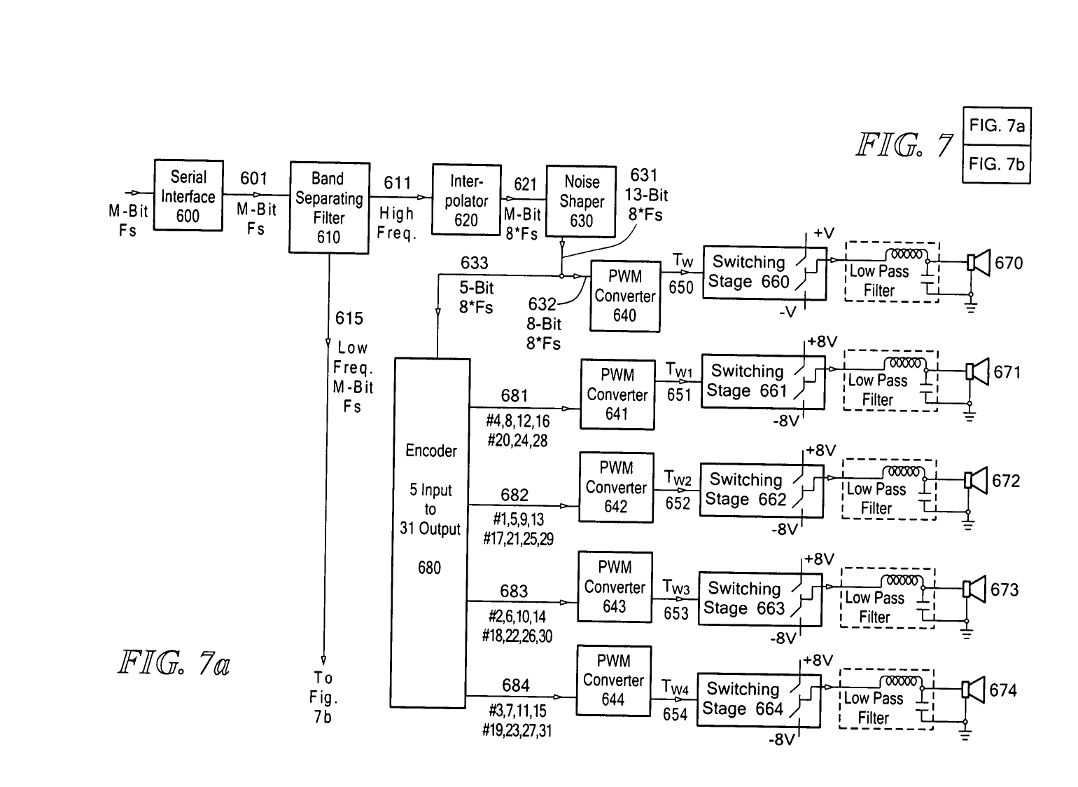

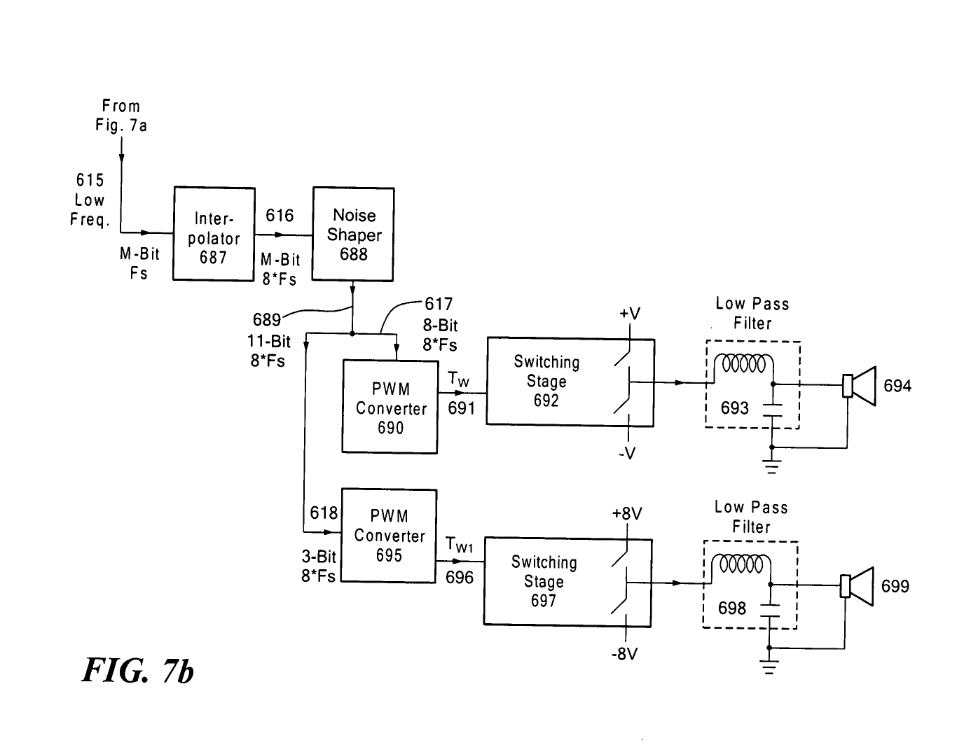

Another approach to the abovementioned variation of the multi-voltage and multi-channel scheme is to have one channel (“PWM channel”) to handle the least significant K bits of the input signal and other channels to handle the most significant J bits of the input signal, all channels using existing PWM control and switching circuitry technology, so that only two voltage levels are required for any one of the channels. The other channels are basically using conventional PWM techniques similar to the PWM channel to produce the different voltage levels in place of the multiple voltage levels provided by the multi-level channels in the system of FIG. 5. Since the other channels normally operate at higher voltage levels than the PWM channel, they are referred to as “high-level” channels to distinguish them from the PWM channel. FIG. 7 shows an example of such a system in accordance with the present invention in which the high-level channels operate at a level 8 times higher than the PWM channel.

Like the system of FIG. 5, the system shown in FIG. 7 is a 32-level PWM digital audio system employing 2-way frequency division. The serial interface 600, band-separating filter 610, interpolator 620, noise shaper 630 and encoder 680 operate in the same manner as their counterparts in FIG. 5. The high frequency M-bit signal 611 which is assumed to be unsigned (a signed data can be converted to an unsigned data by adding an offset to it) goes through the interpolator 620 which up-samples the M-bit data to a sampling rate of 8*Fs to produce the M-bit data 621. The noise shaper 630 converts the M-bit up-sampled data 621 to a coarse-quantized data 631 with reduced resolution of Qh bits (in this example Qh=13) at the same sampling rate of 8*Fs. Each Qh-bit data sample 631 is split into two data samples, one sample of Jh bits 633 (in this example Jh=5) and one sample of Kh bits 632, where Qh=Jh+Kh. The Jh-bit sample 633 represents the most significant bits of the coarse-quantized Qh-bit data sample 631 whereas the Kh-bit sample 632 represents the least significant bits of the coarse-quantized Qh-bit data sample 631.

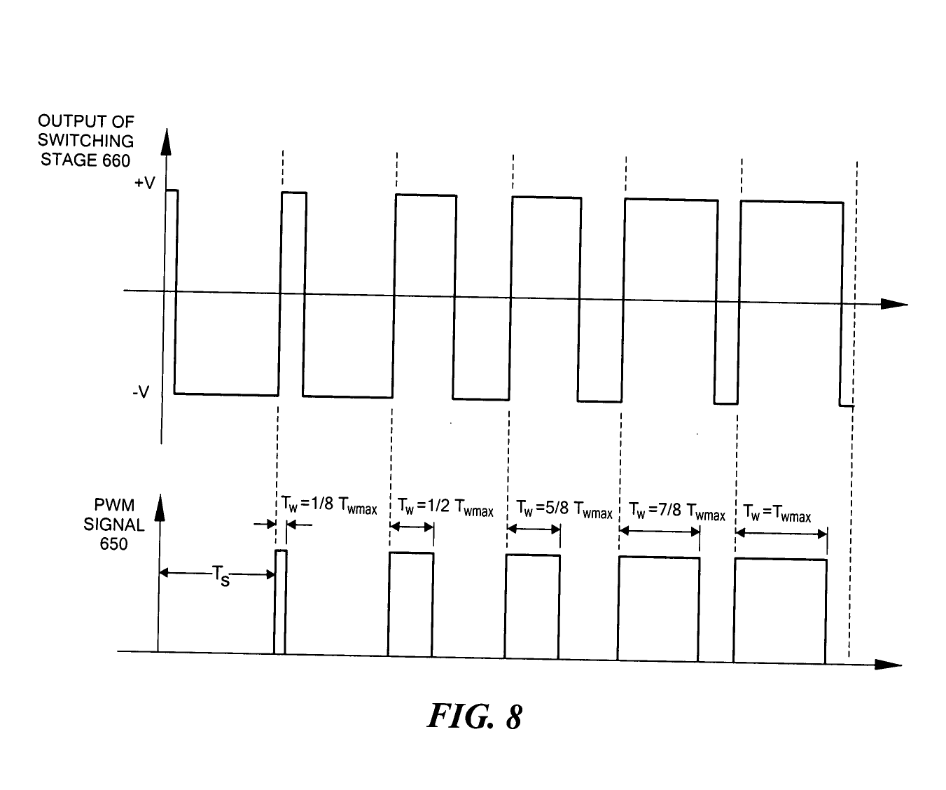

During each sampling cycle, the PWM converter 640 converts the 8-bit data 632 directly to a PWM signal and outputs the PWM signal 650 with pulse width Tw. The PWM signal 650 controls the switching stage 660 such that its electrical output (across a designated load as in the case of an H-bridge configuration) swings between an equal magnitude of positive and negative voltage level V. When the input signal is absent or the pulse width Tw=½*Twmax, where Twmax is the maximum pulse duration in a sampling cycle for the PWM signal, the output of the switching stage 660 has equal positive and negative voltage intervals in a sampling cycle (i.e. 50% duty cycle) . Different values of Tw are represented by different proportion of positive and negative voltage intervals in a sampling cycle. The operation of the switching stage 660 is illustrated in FIG. 8.

An encoder 680 receives the 5-bit data signal 633 and uses this signal to control the states of 31 control lines in four groups 681, 682, 683 and 684. These control lines are shown as numbered from #1 to #31, and they turn ON or OFF in the same manner as their counterparts in FIG. 5. Within the PWM converters 641, 642, 643 and 644, each group of control lines is converted into a binary number representing the number of control lines that are turned ON. Then during each sampling cycle, the PWM converters 641, 642, 643 and 644 generate PWM signals Tw1, Tw2, Tw3 and Tw4 respectively, each having a pulse width increased by an increment equal to Twmax/N for each control line that is ON in the group (681, 682, 683 and 684 respectively) connected to the respective PWM converter (where N corresponds to the number of non-zero voltage levels in the corresponding system of FIG. 5 and is equal to 8 in this example, and Twmax is the maximum pulse duration in a sampling cycle for the PWM signals). No control lines ON corresponds to zero pulse width, and successively greater number of control lines ON corresponds to successively wider pulse width. The PWM signals 651, 652, 653 and 654 control the switching stages 661, 662, 663 and 664 respectively such that their electrical outputs (across each designated load as in the case an H-bridge configuration) swing between an equal magnitude of positive and negative voltage level 8V and they operate in the same manner as switching stage 660.

The low frequency M-bit signal 615, which is assumed to be unsigned (a signed data can be converted to an unsigned data by adding an offset to it) is processed in the same manner as its high frequency counterpart except that the noise shaper 688 converts the M-bit up-sampled data 616 to a coarse-quantized data 689 with reduced resolution of Qw bits (in this example Qw=11) at the same sampling rate of 8*Fs and each Qw-bit data sample 689 is split into two data samples, one sample of Jw bits 618 (in this example Jw=3) and one sample of Kw bits 617 (in this example Kw=8), where Qw=Jw+Kw. The Jw-bit sample 618 represents the most significant bits of the coarse-quantized Qw-bit data sample 689 whereas the Kw-bit sample 617 represents the least significant bits of the coarse-quantized Qw-bit data sample 689.

The operation of the PWM converter 690 and its corresponding switching stage 692 is the same as its high frequency counterpart namely PWM converter 640 and switching stage 660. The electrical output of the switching stage 692 (across a designated load as in the case an H-bridge configuration) swings between an equal magnitude of positive and negative voltage level V. The pulse width of the PWM signal 696 generated by the PWM converter 695 is equal to the value of the Jw-bit signal 618 multiply by Twmax/N (where N corresponds to the number of non-zero voltage levels in the corresponding system of FIG. 5 and is equal to 8 in this example, and Twmax is the maximum pulse duration in a sampling cycle for the PWM signals) Zero value for Jw-bit signal 618 corresponds to zero pulse width, and successively greater value corresponds to successively wider pulse width. The PWM signal 696 controls the switching stage 697 such that its electrical output (across a designated load as in the case an H-bridge configuration) swings between an equal magnitude of positive and negative voltage level 8V and it operates in the same manner as switching stage 660.

It should also be noted that the respective outputs of the low-frequency band and high-frequency band may need to be equalized as in the system of FIG. 5.

In practice, in order to compensate for the physical differences of the channels or the different responses of the channels to different magnitude PWM signals in the system of FIG. 7, the magnitude of the positive and negative voltage level for the high-level channels may not be an exact integer multiple of the level for the PWM channel, and the maximum pulse duration in a sampling cycle of the pulse width modulated signal of the PWM channel and the high-level channels may not be the same.

It can be seen that the system of FIG. 7 produces the same acoustic effect as the system of FIG. 5 and has the advantages of being able to make use of the existing PWM techniques and requiring fewer voltage levels. However, it requires one more channel in each frequency band than the system of FIG. 5 for the same resolution.

All the electronic circuitry of the digital audio system of the present invention can be incorporated in an IC chip or chip set and therefore the physical size of the system is mainly determined by the size of its power supply and L-C low pass filters.

For systems employing multiple output channels such as in FIGS. 4, 5 and 7, it may be convenient to place the entire system including all the loudspeakers in one enclosure to eliminate the necessity of running many wires from the outputs to the loudspeakers. Also, each channel output can be driven by a separate power supply, each based on the same reference voltage level as the others. In this way, a number of smaller power supplies, each dedicated to one output and not affected by the other outputs, can be used to produce a large overall system output power, such as 500 watts for example.

For systems employing multiple voltage levels such as in FIGS. 2 and 5, each switching output stage can be configured with switches in a multiple H-bridge configuration so that the load (i.e., loudspeaker and L-C low pass filter) connected to the switches can be driven in a push-pull fashion. In such configuration, the load is connected to multiple H-bridge switches such that either zero voltage is applied to both ends of the load or a positive (or negative) voltage is applied to one end of the load and a zero voltage is applied to the other end at any given time. In such a configuration, current flowing through the load in one direction represents one positive voltage level; current flowing in the reverse direction represents one negative voltage level; and no current flowing through the load represents the zero voltage level.

Additionally, the control of the magnitude of the outputs of the systems can be achieved by varying the single or multiple voltage levels in concert, which can be accomplished for example by varying a fixed reference voltage level on which all the voltage levels are based.

The multi-level PWM technique described herein may generally be utilized in other types of systems that generate an analog output from a digital representation and especially in systems which have their performance limited by the limitation of ordinary PWM techniques. The term analog output should be taken in a broad sense to mean any physical output especially physical output of additive nature which means similar physical outputs can be summed together to form a final physical output e.g. liquid, gaseous, thermal, electromagnetic, or acoustic output etc. Furthermore, the physical output generated from a multi-level electrical signal or by additively combining a plurality of physical outputs (also referred to as analog component outputs) generated from corresponding electrical signals from separate channels or by both multi-level electrical signals and multiple channels whose respective physical outputs are additively combined as disclosed herein shall mean the physical outputs that are converted from their corresponding electrical signals by their converting devices or arrangements. For example, in the digital audio systems, sounds are generated from electrical signals by an arrangement of L-C low pass filters and loudspeakers and in case of liquid outputs, it may mean pumps or fuel injecting devices etc. It will be apparent to those skilled in the art that other modifications to and variations of the disclosed methods and apparatus are possible without departing from the inventive concepts disclosed herein, and therefore the invention should not be viewed as limited except to the full scope and spirit of the appended claims.

What is claimed is:

1. Apparatus for controlling switching circuitry for generating an analog output from a digital signal, the digital signal carrying multi-bit values at a sampling rate, the apparatus including a first digital signal derived from the digital signal, the first digital signal including first and second digital sub-signals carrying respective least and most significant components of the multi-bit values carried by the first digital signal, and further comprising:
pulse width modulation (PWM) circuitry operative to generate a pulse width modulated signal based on the first digital sub-signal; and
switch control circuitry under the control of the pulse width modulated signal and the second digital sub-signal and operative via the switching circuitry to produce the analog output.

2. Apparatus according to claim 1, wherein the first digital signal is the same as the digital signal.

3. Apparatus according to claim 1, further comprising a noise shaper operative to generate the first digital signal which is coarsely quantized from the digital signal.

4. Apparatus according to claim 1, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

5. Apparatus according to claim 1, wherein:
the analog output is generated from a multi-level electrical signal which includes a pulse width modulated component and a multi-level component;
the switching circuitry includes a plurality of switches each operative in response to assertion of a corresponding one of switch control signals to provide one of a set of distinct levels of the multi-level electrical signal;
the PWM circuitry includes a pulse width modulation (PWM) converter operative to generate the pulse width modulated signal based on the first digital sub-signal; and
the switch control circuitry includes a level selector operative to assert each of the switch control signals based on the pulse width modulated signal, a maximum-width-pulse signal and the second digital sub-signal, the maximum-width-pulse signal establishing the maximum permissible pulse duration in a sampling cycle for the pulse width modulated signal.

6. Apparatus according to claim 5, wherein:
the assertion of a first one of the switch control signals by the level selector in response to a corresponding value of the second digital sub-signal establishes a base level of the multi-level electrical signal for a sampling cycle; and
during a given cycle, the level selector is further operative in response to the pulse width modulated signal to assert a second one of the switch control signals to provide a pulse level of the multi-level electrical signal, the pulse level of the multi-level electrical signal being different from the base level of the multi-level electrical signal.

7. Apparatus according to claim 6, wherein the second switch control signal is asserted during first periods of the cycle as established by the pulse width modulated signal, the first switch control signal is asserted during second periods which are outside the first periods of the cycle and within the maximum pulse duration in the cycle as established by the maximum-width-pulse signal, and neither the first switch control signal nor the second switch control signal but a third switch control signal is asserted during a third period of the cycle constituting a remainder portion beyond the maximum permissible pulse duration to provide an idle level of the multi-level electrical signal.

8. Apparatus according to claim 6, wherein the lowest value of the second digital sub-signal corresponds to the lowest base level of the multi-level electrical signal which is also the lowest level of the multi-level electrical signal, and successively higher values of the second digital sub-signal correspond to successively higher base levels of the multi-level electrical signal.

9. Apparatus according to claim 5, wherein each of the levels in the set of distinct levels of the multi-level electrical signal is a corresponding ratio of a reference level.

10. Apparatus according to claim 5, wherein the plurality of switches are arranged in a multiple H-bridge configuration and are operative to apply either (1)zero voltage level to both ends of a load connected to the switches, or (2) a positive or negative voltage level to one end of the load and a zero voltage level to the other end at any given time, such that current flowing through the load in one direction represents one positive voltage level, current flowing through the load in the reverse direction represents one negative voltage level, and no current flowing through the load represents a zero voltage level.

11. Apparatus according to claim 5, wherein the analog output is a physical output.

12. Apparatus according to claim 11, wherein the physical output is an acoustic output.

13. Apparatus according to claim 5, wherein control of the magnitude of the analog output is obtained by controlling the magnitude of each of the levels in the set of distinct levels of the multi-level electrical signal.

14. Apparatus according to claim 5, wherein:
the multi-level electrical signal is one of a plurality of multi-level electrical signals from which the analog output is generated, each multi-level electrical signal being generated from a corresponding one of a plurality of channels;
the plurality of switches is one set of a plurality of sets of switches, each set being associated with a corresponding one of the channels, and the switch control signals are one set of a plurality of first sets of control signals, each first set of control signals being associated with a corresponding channel, each switch in the set of switches for each channel being operative in response to assertion of a corresponding one of the first set of control signals for the channel to provide one of the set of distinct levels of the multi-level electrical signal of the channel;
the level selector is one of a plurality of level selectors each being associated with a corresponding one of the channels, the level selector of each channel being operative to assert each of the first set of control signals of the channel in response to a corresponding one of a plurality of second sets of control signals; and
the switch control circuitry further includes an encoder operative to generate the second sets of control signals based on the second digital sub-signal.

15. Apparatus for controlling switching circuitry for generating an analog output from a digital signal, the digital signal carrying multi-bit values at a sampling rate, the apparatus including a first digital signal derived from the digital signal, the first digital signal including first and second digital sub-signals carrying respective least and most significant components of the multi-bit values carried by the first digital signal, the analog output being generated by additively combining a plurality of analog component outputs from a corresponding plurality of channels, each analog component output being generated from a corresponding one of a plurality of electrical signals, the switching circuitry including a plurality of switches, each switch being associated with a corresponding one of the channels, the switch for the first channel being operative in response to assertion of a pulse width modulated signal to generate a corresponding one of the electrical signals, the switch for each of the other channels being operative based on assertion of a corresponding one of switch control signals to generate a predetermined level on the electrical signal of the corresponding channel, and the apparatus further comprising:
pulse width modulation (PWM) circuitry operative to generate the pulse width modulated signal based on the first digital sub-signal; and
switch control circuitry operative to assert different numbers of the switch control signals based on the second digital sub-signal.

16. Apparatus according to claim 15, wherein the first digital signal is the same as the digital signal.

17. Apparatus according to claim 15, further comprising a noise shaper operative to generate the first digital signal which is coarsely quantized from the digital signal.

18. Apparatus according to claim 15, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

19. Apparatus according to claim 15, wherein each of the electrical signals is generated with the same predetermined level.

20. Apparatus according to claim 15, wherein the switch control circuitry includes an encoder operative to assert zero number of switch control signals when the value of the second digital sub-signal is zero, and successively greater numbers of the switch control signals for successively higher values of the second digital sub-signal.

21. Apparatus according to claim 15, wherein:
the plurality of electrical signals include fixed-pulse-width electrical signals and a variable-pulse-width electrical signal, and the analog component outputs include fixed-pulse-width analog component outputs and a variable-pulse-width analog component output generated from the fixed-pulse-width electrical signals and a variable-pulse-width electrical signal respectively;
the analog output is further generated by additively combining the fixed-pulse-width analog component outputs with the variable-pulse-width analog component output;
the switching circuitry includes the switch for the first channel operative in response to assertion of the pulse width modulated signal to generate the variable-pulse-width electrical signal, and the other switches each operative in response to assertion of a corresponding one of switch control signals and a maximum-width-pulse signal to generate a predetermined level on the corresponding fixed-pulse-width electrical signal, the maximum-width-pulse signal establishing the maximum permissible pulse duration in a sampling cycle for the pulse width modulated signal; and
the PWM circuitry includes a pulse width modulation (PWM) converter operative to generate the pulse width modulated signal based on the first digital sub-signal.

22. Apparatus according to claim 21, wherein the switch for the first channel is operative in response to assertion of the pulse width modulated signal to provide one of the two predetermined levels of the variable-pulse-width electrical signal; the two predetermined levels of the variable-pulse-width electrical signal are an equal magnitude of positive and negative voltage level; and the different proportions of the positive and negative voltage level intervals of the variable-pulse-width electrical signal during a corresponding sampling cycle of the pulse width modulated signal correspond to the different pulse widths of the pulse width modulated signal in the sampling cycle.

23. Apparatus according to claim 15, wherein the plurality of switches are not coupled to a single power supply.

24. Apparatus according to claim 15, wherein:
each of the electrical signals is a multi-level electrical signal generated from a corresponding channel;
each of the switches is a first switch of a corresponding set of switches in a corresponding one of the channels, and each of the switch control signals is one of a first set of control signals of the corresponding channel, each switch within each set of switches for each channel being operative in response to assertion of a corresponding one of the first set of control signals of the channel to generate one of a set of distinct levels of the multi-level electrical signal of the channel; and
the switch control circuitry further includes a plurality of level selectors each associated with a corresponding channel, each level selector being operative to assert each of the first set of control signals of the channel in response to a corresponding one of a plurality of second sets of control signals, and further includes an encoder operative to generate the second sets of control signals based on the second digital sub-signal.

25. Apparatus according to claim 15, wherein the digital signal is a first frequency component and each of the analog component outputs is in a first frequency band associated with the first frequency component, the analog component outputs in the first frequency band being additively combined to form a first frequency analog output, the analog output being generated by additively combining the first frequency analog output in the first frequency band with a second frequency analog output in a second frequency band associated with a second frequency component, a third digital signal carrying multi-bit values at a sampling rate being derived from the second frequency component and wherein the channels are channels in the first frequency band and the switching circuitry, PWM circuitry, pulse width modulated signal, maximum-width-pulse signal, switch control signals and switch control circuitry are first switching circuitry, first PWM circuitry, first pulse width modulated signal, first maximum-width-pulse signal, first switch control signals and first switch control circuitry respectively associated with the first frequency band, and further comprising:
a band-separating filter operative to generate the first and second frequency components of a wide-band digital signal;
second switching circuitry including a switch operative in response to assertion of a second pulse width modulated signal to generate an electrical signal from which the second frequency analog output is generated; and
second PWM circuitry operative to generate the second pulse width modulated signal based on the third digital signal.

26. Apparatus according to claim 25, wherein the third digital signal is the same as the second frequency component.

27. Apparatus according to claim 25, wherein:
the third digital signal includes third and fourth digital sub-signals carrying respective least and most significant components of the multi-bit values carried by the third digital signal;
the electrical signal is one of a plurality of electrical signals in the second frequency band, each electrical signal being generated from a corresponding one of a plurality of channels in the second frequency band, the second frequency analog output being generated by additively combining a plurality of analog component outputs from the plurality of channels in the second frequency band, each analog component output in the second frequency band being generated from a corresponding one of a plurality of electrical signals of the channels in the second frequency band;
the switch in the second switching circuitry is one of a plurality of switches, each switch being associated with a corresponding one of the channels in the second frequency band, the switch for the first channel in the second frequency band being operative in response to assertion of the second pulse width modulated signal to generate a corresponding one of the electrical signals, the switch for each of the other channels in the second frequency band being operative in response to assertion of a corresponding one of second switch control signals and a second maximum-width-pulse signal to generate a predetermined level on the electrical signal of the corresponding channel in the second frequency band, the second maximum-width-pulse signal establishing the maximum permissible pulse duration in a sampling cycle for the second pulse width modulated signal; and
the second PWM circuitry is operative to generate the second pulse width modulated signal based on the third digital sub-signal;
and further comprising second switch control circuitry including an encoder operative to assert different numbers of the second switch control signals based on the fourth digital sub-signal.

28. Apparatus according to claim 27, further comprising a noise shaper operative to generate the third digital signal which is coarsely quantized from the second frequency component.

29. Apparatus according to claim 27, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

30. Apparatus according to claim 25, further comprising a noise shaper operative to generate the third digital signal which is coarsely quantized from the second frequency component.

31. Apparatus according to claim 25, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

32. Apparatus according to claim 25, wherein the first frequency band is a higher frequency band with more channels and the second frequency band is a lower frequency band with fewer channels.

33. Apparatus according to claim 15, wherein the analog output is a physical output.

34. Apparatus according to claim 33, wherein the physical output is an acoustic output.

35. Apparatus according to claim 15, wherein control of the magnitude of the analog output is obtained by controlling the magnitude of the predetermined levels used by the switching circuitry of the channels.

36. Apparatus for controlling switching circuitry for generating an analog output from a digital signal, the digital signal carrying multi-bit values at a sampling rate, the apparatus including a first digital signal derived from the digital signal, the first digital signal including first and second digital sub-signals carrying respective least and most significant components of the multi-bit values carried by the first digital signal, the analog output being generated by additively combining analog component outputs from first and second channels, the analog component output of the second channel being generated from a multi-level electrical signal, the switching circuitry including a set of switches each operative based on assertion of a corresponding one of first set of control signals for the second channel to provide one of a set of distinct levels of the multi-level electrical signal of the second channel, and the apparatus further comprising:
pulse width modulation (PWM) circuitry operative to generate a pulse width modulated signal, the pulse width modulated signal being based on the first digital sub-signal and operative via the switching circuitry to generate an electrical signal from which the analog component output of the first channel is generated; and
switch control circuitry including a level selector associated with the second channel operative to assert each of the first set of control signals of the second channel based on the second digital sub-signal and a maximum-width-pulse signal, the maximum-width-pulse signal establishing the maximum permissible pulse duration in a sampling cycle for the pulse width modulated signal.

37. Apparatus according to claim 36, wherein the first digital signal is the same as the digital signal.

38. Apparatus according to claim 36, wherein:
the second channel is one of a plurality of fixed-pulse-width channels;
the multi-level electrical signal is one of a plurality of multi-level electrical signals, each multi-level electrical signal being generated from a corresponding one of a plurality of fixed-pulse-width channels;
the analog output is generated by additively combining a plurality of analog component outputs from the first channel and the plurality of fixed-pulse-width channels, the analog component output of each fixed-pulse-width channel being generated from a corresponding one of the multi-level electrical signals;
the set of switches is one set of a plurality of sets of switches, each set being associated with a corresponding one of the fixed-pulse-width channels, the first set of control signals for the second channel are one set of a plurality of first sets of control signals for the plurality of fixed-pulse-width channels, each first set of control signals for the fixed-pulse-width channels being associated with a corresponding fixed-pulse-width channel, each switch in the set of switches for each fixed-pulse-width channel being operative in response to assertion of a corresponding one of the first set of control signals for the corresponding fixed-pulse-width channel to provide one of the set of distinct levels of the multi-level electrical signal of the corresponding fixed-pulse-width channel;
the level selector associated with the second channel is one of a plurality of level selectors each being associated with a corresponding one of the fixed-pulse-width channels, the level selector of each fixed-pulse-width channel being operative to assert each of the corresponding first set of control signals of the fixed-pulse-width channel in response to a corresponding one of a plurality of second sets of control signals and the maximum-width-pulse signal; and
the switch control circuitry further includes an encoder operative to generate the second sets of control signals based on the second digital sub-signal.

39. Apparatus according to claim 38, wherein the control signals comprising the second sets of control signals generated by the encoder based on the second digital sub-signal are numbered consecutively starting from one and corresponding to the value of the second digital sub-signal such that all control signals having a number less than or equal to the value of the second digital sub-signal will be turned on else turned off and the numbered control signals are interleaved among the different sets of second sets of control signals according to the numbers assigned to them.

40. Apparatus according to claim 36, wherein (i) the electrical signal from which the analog component output of the first channel is generated is a multi-level electrical signal, and (ii) the level selector associated with the second channel is operative to assert each of the first set of control signals of the second channel in response to a second set of control signals for the second channel, and (iii) the switch control circuitry includes an encoder operative to generate the second sets of control signals for the first and second channels in response to the second digital sub-signal, and further comprising:
a set of switches for the first channel within the switching circuitry, each switch in the set of switches for the first channel being operative based on assertion of a corresponding one of first set of control signals for the first channel to provide one of the set of distinct levels of the multi-level electrical signal of the first channel; and
a level selector for the first channel within the switch control circuitry operative to assert each of the first set of control signals of the first channel based on the. pulse width modulated signal, the maximum-width-pulse signal and the second set of control signals of the first channel.

41. Apparatus according to claim 36, wherein:
the multi-level electrical signal of the second channel is a fixed-pulse-width electrical signal, the analog component output of the second channel is a fixed-pulse-width analog component output, and the analog component output of the first channel is a variable-pulse-width analog component output generated from a variable-pulse-width electrical signal; and
the switching circuitry includes a set of switches for the first channel operative in response to assertion of the pulse width modulated signal to generate the variable-pulse-width electrical signal.

42. Apparatus according to claim 41, wherein the set of switch for the first channel is operative in response to assertion of the pulse width modulated signal to provide one of the two predetermined levels of the variable-pulse-width electrical signal; the two predetermined levels of the variable-pulse-width electrical signal are an equal magnitude of positive and negative voltage level; and the different proportions of the positive and negative voltage level intervals of the variable-pulse-width electrical signal during a corresponding sampling cycle of the pulse width modulated signal correspond to the different pulse widths of the pulse width modulated signal in the sampling cycle.

43. Apparatus according to claim 36, further comprising a noise shaper operative to generate the first digital signal which is coarsely quantized from the digital signal.

44. Apparatus according to claim 36, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

45. Apparatus according to claim 36, wherein the digital signal is a first frequency component and each of the analog component outputs is in a first frequency band associated with the first frequency component, the analog component outputs in the first frequency band being additively combined to form a first frequency analog output, the analog output being generated by additively combining the first frequency analog output in the first frequency band with a second frequency analog output in a second frequency band associated with a second frequency component, a third digital signal carrying multi-bit values at a sampling rate being derived from the second frequency component and wherein the channels are channels in the first frequency band and the switching circuitry, pulse width modulated signal, maximum-width-pulse signal, PWM circuitry, level selector and switch control circuitry are first switching circuitry, first pulse width modulated signal, first maximum-width-pulse signal, first PWM circuitry, first level selector and first switch control circuitry respectively associated with the first frequency band, and further comprising:
a band-separating filter operative to generate the first and second frequency components of a wide-band digital signal;
second switching circuitry operative in response to assertion of a second pulse width modulated signal to generate an electrical signal from which the second frequency analog output is generated; and
second pulse width modulation (PWM) circuitry operative to generate the second pulse width modulated signal based on the third digital signal.

46. Apparatus according to claim 45, wherein the third digital signal is the same as the second frequency component.

47. Apparatus according to claim 45, wherein:
the third digital signal includes third and fourth digital sub-signals carrying respective least and most significant components of the multi-bit values carried by the third digital signal;
the electrical signal is a multi-level electrical signal from which the second frequency analog output is generated;
second switching circuitry is operative in response to assertion of a third set of control signals to generate the multi-level electrical signal; and
second switch control circuitry includes a second level selector operative to assert each of the third set of control signals in response to the second pulse width modulated signal, a second maximum-width-pulse signal and the fourth digital sub-signal, the second maximum-width-pulse signal establishing the maximum permissible pulse duration in a sampling cycle for the second pulse width modulated signal.

48. Apparatus according to claim 47, wherein:
the multi-level electrical signal is one of a plurality of multi-level electrical signals in the second frequency band, each multi-level electrical signal in the second frequency band being generated from a corresponding one of a plurality of channels in the second frequency band;
the second frequency analog output is generated by additively combining a plurality of analog component outputs from the plurality of channels in the second frequency band, the analog component output of each channel in the second frequency band being generated from a corresponding one of the multi-level electrical signals;
the second switching circuitry includes a plurality of sets of switches, each set being associated with a corresponding one of the channels in the second frequency band, and the third set of control signals is one set of a plurality of third sets of control signals, each third set of control signals being associated with a corresponding channel in the second frequency band, each switch in the set of switches for each channel in the second frequency band being operative in response to assertion of a corresponding one of the third set of control signals for the corresponding channel in the second frequency band to provide one of a set of distinct levels of the multi-level electrical signal of the corresponding channel in the second frequency band;
the second level selector is one of a plurality of second level selectors each being associated with a corresponding one of the channels in the second frequency band, the second level selector associated with a first one of the channels in the second frequency band being operative to assert each of the third set of control signals of the first channel in the second frequency band based on the second pulse width modulated signal, the second maximum-width-pulse signal and a fourth set of control signals for the first channel in the second frequency band, each of the other second level selectors being operative to assert control signals of the third set of control signals of the corresponding channel in the second frequency band in response to a fourth set of control signals for the corresponding channel in the second frequency band and the second maximum-width-pulse signal; and
the second switch control circuitry further includes an encoder operative to generate the fourth set of control signals for each channel in the second frequency band based on the fourth digital sub-signal.

49. Apparatus according to claim 47, further comprising a noise shaper operative to generate the third digital signal which is coarsely quantized from the second frequency component.

50. Apparatus according to claim 47, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

51. Apparatus according to claim 45, further comprising a noise shaper operative to generate the third digital signal which is coarsely quantized from the second frequency component.

52. Apparatus according to claim 45, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

53. Apparatus according to claim 45, wherein the first frequency band is a higher frequency band with more channels and the second frequency band is a lower frequency band with fewer channels.

54. Apparatus according to claim 36, wherein the analog output is a physical output.

55. Apparatus according to claim 54, wherein the physical output is an acoustic output.

56. Apparatus according to claim 36, wherein each of the levels in the set of distinct levels of each electrical signal is a corresponding ratio of a reference level.

57. Apparatus according to claim 56, wherein control of the magnitude of the analog output is obtained by controlling the magnitude of the reference level.

58. Apparatus according to claim 36, wherein the switches in each set of switches are arranged in a multiple H-bridge configuration and are operative to apply either (1)zero voltage level to both ends of a load connected to the switches, or (2) a positive or negative voltage level to one end of the load and a zero voltage level to the other end at any given time, such that current flowing through the load in one direction represents one positive voltage level, current flowing through the load in the reverse direction represents one negative voltage level, and no current flowing through the load represents a zero voltage level.

59. Apparatus according to claim 36, wherein the plurality of sets of switches are not coupled to a single power supply.

60. A digital audio system for generating an acoustic audio signal from a digital signal, the digital signal carrying multi-bit values at a sampling rate, the digital audio system including a first digital signal derived from the digital signal, the first digital signal including first and second digital sub-signals carrying respective least and most significant components of the multi-bit audio values carried by the first digital signal, the acoustic audio signal being generated from a multi-level electrical signal, and the system further comprising:
a loudspeaker;
a low-pass filter coupled to the loudspeaker;
switching circuitry coupled to the low-pass filter, the switching circuitry including a plurality of switches each operative in response to assertion of a corresponding one of switch control signals to provide one of a set of distinct levels of a multi-level electrical signal, the multi-level electrical signal being provided to the low-pass filter;
pulse width modulation (PWM) circuitry operative to generate a pulse width modulated signal based on the first digital sub-signal; and
switch control circuitry including a level selector operative to assert each of the switch control signals based on the pulse width modulated signal, a maximum-width-pulse signal and the second digital sub-signal, the maximum-width-pulse signal establishing the maximum permissible pulse duration in a sampling cycle for the pulse width modulated signal.

61. A digital audio system according to claim 60, wherein the first digital signal is the same as the digital signal.

62. A digital audio system according to claim 60, wherein the plurality of switches are arranged in a multiple H-bridge configuration and are operative to apply either (1) zero voltage level to both ends of a load connected to the switches, the load comprising of a low-pass filter coupled to a loudspeaker, or (2) a positive or negative voltage level to one end of the load and a zero voltage level to the other end at any given time, such that current flowing through the load in one direction represents one positive voltage level, current flowing through the load in the reverse direction represents one negative voltage level, and no current flowing through the load represents a zero voltage level.

63. A digital audio system according to claim 60, wherein the switching circuitry is operative to select positive and negative voltages to generate the acoustic audio signal.

64. A digital audio system according to claim 60, wherein each of the levels in the set of distinct levels of the multi-level electrical signal is a corresponding ratio of a reference level and control of the volume of the acoustic audio signal is obtained by controlling the magnitude of the reference level.

65. A digital audio system according to claim 60, further comprising a noise shaper operative to generate the first digital signal which is coarsely quantized from the digital signal.

66. A digital audio system according to claim 60, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

67. A digital audio system for generating an acoustic audio signal from a digital signal, the digital signal carrying multi-bit values at a sampling rate, the digital audio system including a first digital signal derived from the digital signal, the first digital signal including first and second digital sub-signals carrying respective least and most significant components of the multi-bit audio values carried by the first digital signal, the acoustic audio signal being generated by additively combining a plurality of acoustic audio component signals from a corresponding plurality of channels, each acoustic audio component signal being generated from a corresponding one of a plurality of pulse electrical signals which include fixed-width pulse electrical signals and a variable-width pulse electrical signal, and the system further comprising:
a plurality of loudspeakers each associated with a corresponding one of the channels;
a plurality of low-pass filters each coupled to a corresponding one of the loudspeakers;
switching circuitry coupled to the low-pass filters, the switching circuitry including a plurality of switches, each switch being associated with a corresponding one of the channels, the switch for one of the channels being operative on assertion of a pulse width modulated signal to generate the variable-width pulse electrical signal, the switch for each of the other channels being operative on assertion of a corresponding one of switch control signals and a maximum-width-pulse signal to generate the corresponding fixed-width pulse electrical signal, the maximum-width-pulse signal establishing the maximum permissible pulse duration in a sampling cycle for the pulse width modulated signal, each pulse electrical signal being provided to the corresponding low-pass filter;
pulse width modulation (PWM) circuitry operative to generate the pulse width modulated signal based on the first digital sub-signal; and
switch control circuitry including an encoder operative to assert different numbers of the switch control signals based on the second digital sub-signal.

68. A digital audio system according to claim 67, wherein the first digital signal is the same as the digital signal.

69. A digital audio system according to claim 67, further comprising a noise shaper operative to generate the first digital signal which is coarsely quantized from the digital signal.

70. A digital audio system according to claim 67, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

71. A digital audio system according to claim 67, wherein the digital signal is a first frequency component and each of the acoustic audio component signals is in a first frequency band associated with the first frequency component, the acoustic audio component signals in the first frequency band being additively combined to form a first frequency acoustic audio signal, the acoustic audio signal being generated by additively combining the first frequency acoustic audio signal in the first frequency band with a second frequency acoustic audio signal in a second frequency band associated with a second frequency component, a third digital signal carrying multi-bit values at a sampling rate being derived from the second frequency component and wherein the channels are channels in the first frequency band and the plurality of loudspeakers, plurality of low-pass filters, switching circuitry, switch control circuitry, pulse width modulated signal, maximum-width-pulse signal and PWM circuitry are a plurality of first loudspeakers, a plurality of first low-pass filters, first switching circuitry, first switch control circuitry, first pulse width modulated signal, first maximum-width-pulse signal and first PWM circuitry respectively associated with the first frequency band, and further comprising:
a second loudspeaker associated with the second frequency band;
a second low-pass filter coupled to the second loudspeaker;
a band-separating filter operative to generate the first and second frequency components of a wide-band digital signal;
second switching circuitry coupled to the second low-pass filter, the second switching circuitry including a switch being operative in response to assertion of a second pulse width modulated signal to generate a pulse electrical signal from which the second frequency acoustic audio signal is generated; and
second pulse width modulation (PWM) circuitry operative to generate the second pulse width modulated signal based on the third digital signal.

72. A digital audio system according to claim 71, wherein the third digital signal is the same as the second frequency component.

73. A digital audio system according to claim 71, further comprising a noise shaper operative to generate the third digital signal which is coarsely quantized from the second frequency component.

74. A digital audio system according to claim 71, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

75. A digital audio system according to claim 71, wherein:
the third digital signal includes third and fourth digital sub-signals carrying respective least and most significant components of the multi-bit values carried by the third digital signal;
the second loudspeaker is one of a plurality of second loudspeakers each associated with a corresponding one of the channels in the second frequency band;
the second low-pass filter is one of a plurality of second low-pass filters each coupled to a corresponding one of the second loudspeakers;
the pulse electrical signal is one of a plurality of pulse electrical signals in the second frequency band, each pulse electrical signal being generated from a corresponding one of a plurality of channels in the second frequency band, the second frequency acoustic audio signal being generated by additively combining a plurality of acoustic audio component signals from the plurality of channels in the second frequency band, each acoustic audio component signal in the second frequency band being generated from a corresponding one of a plurality of pulse electrical signals which include fixed-width pulse electrical signals and a variable-width pulse electrical signal in the second frequency band;
each pulse electrical signal generated from a corresponding one of the channels in the second frequency band is provided to its corresponding second low-pass filter;
the switch in the second switching circuitry is one of a plurality of switches, each switch being associated with a corresponding one of the channels in the second frequency band, the switch for one of the channel in the second frequency band being operative in response to assertion of the second pulse width modulated signal to generate the variable-width pulse electrical signal in the second frequency band, the switch for each of the other channels in the second frequency band being operative in response to assertion of a corresponding one of second switch control signals and a second maximum-width-pulse signal to generate the fixed-width pulse electrical signal of the corresponding channel in the second frequency band, the second maximum-width-pulse signal establishing the maximum permissible pulse duration in a sampling cycle for the second pulse width modulated signal; and
the second PWM circuitry is operative to generate the second pulse width modulated signal based on the third digital sub-signal;
and further comprising second switch control circuitry including an encoder operative to assert different numbers of the second switch control signals based on the fourth digital sub-signal.

76. A digital audio system according to claim 75, further comprising a noise shaper operative to generate the third digital signal which is coarsely quantized from the second frequency component.

77. A digital audio system according to claim 75, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

78. A digital audio system according to claim 71, wherein the first frequency band is a higher frequency band with more channels and the second frequency band is a lower frequency band with fewer channels.

79. A digital audio system according to claim 67, wherein the plurality of switches are not coupled to a single power supply.

80. A digital audio system according to claim 67, the digital audio system being contained within a single enclosure.

81. A digital audio system according to claim 67, wherein control of the volume of the acoustic audio signal is obtained by controlling the magnitude of a reference level used by the switching circuitry to establish the levels of the pulse electrical signals.

82. A digital audio system for generating an acoustic audio signal from a digital signal, the digital signal carrying multi-bit values at a sampling rate, the digital audio system including a first digital signal derived from the digital signal, the first digital signal including first and second digital sub-signals carrying respective least and most significant components of the multi-bit audio values carried by the first digital signal, the acoustic audio signal being generated by additively combining acoustic audio component signals from first and second channels, the acoustic audio component signal of the second channel being generated from a multi-level electrical signal, and the system further comprising:
a plurality of loudspeakers each associated with a corresponding one of the channels;
a plurality of low-pass filters each coupled to a corresponding one of the loudspeakers;
switching circuitry including a set of switches each operative based on assertion of a corresponding one of first set of control signals for the second channel to provide one of a set of distinct levels of the multi-level electrical signal of the second channel;
pulse width modulation (PWM) circuitry operative to generate a pulse width modulated signal, the pulse width modulated signal being based on the first digital sub-signal and operative via the switching circuitry to generate an electrical signal from which the acoustic audio component signal of the first channel is generated;
each electrical signal being provided to its corresponding low-pass filter; and
switch control circuitry including a level selector associated with the second channel operative to assert each of the first set of control signals of the second channel based on the second digital sub-signal and a maximum-width-pulse signal, the maximum-width-pulse signal establishing the maximum permissible pulse duration in a sampling cycle for the pulse width modulated signal.

83. A digital audio system according to claim 82, wherein the first digital signal is the same as the digital signal.

84. A digital audio system according to claim 82, wherein:
the second channel is one of a plurality of fixed-pulse-width channels;
the multi-level electrical signal is one of a plurality of multi-level electrical signals, each multi-level electrical signal being generated from a corresponding one of a plurality of fixed-pulse-width channels;
the acoustic audio signal is generated by additively combining a plurality of acoustic audio component signals from the first channel and the plurality of fixed-pulse-width channels, the acoustic audio component signal of each fixed-pulse-width channel being generated from a corresponding one of the multi-level electrical signals;
the set of switches is one set of a plurality of sets of switches, each set being associated with a corresponding one of the fixed-pulse-width channels, the first set of control signals for the second channel are one set of a plurality of first sets of control signals for the plurality of fixed-pulse-width channels, each first set of control signals for the fixed-pulse-width channels being associated with a corresponding fixed-pulse-width channel, each switch in the set of switches for each fixed-pulse-width channel being operative in response to assertion of a corresponding one of the first set of control signals for the corresponding fixed-pulse-width channel to provide one of the set of distinct levels of the multi-level electrical signal of the corresponding fixed-pulse-width channel;
the level selector associated with the second channel is one of a plurality of level selectors each being associated with a corresponding one of the fixed-pulse-width channels, the level selector of each fixed-pulse-width channel being operative to assert each of the corresponding first set of control signals of the fixed-pulse-width channel in response to a corresponding one of a plurality of second sets of control signals and the maximum-width-pulse signal; and
the switch control circuitry further includes an encoder operative to generate the second sets of control signals based on the second digital sub-signal.

85. A digital audio system according to claim 82, wherein (i) the electrical signal from which the acoustic audio component signal of the first channel is generated is a multi-level electrical signal, (ii) the level selector associated with the second channel is operative to assert each of the first set of control signals of the second channel in response to a second set of control signals for the second channel, and (iii) the switch control circuitry includes an encoder operative to generate the second sets of control signals for the first and second channels in response to the second digital sub-signal, and further comprising:
a set of switches for the first channel within the switching circuitry, each switch in the set of switches for the first channel being operative based on assertion of a corresponding one of first set of control signals for the first channel to provide one of the set of distinct levels of the multi-level electrical signal of the first channel; and
a level selector for the first channel within the switch control circuitry operative to assert each of the first set of control signals of the first channel based on the pulse width modulated signal, the maximum-width-pulse signal and the second set of control signals of the first channel.

86. A digital audio system according to claim 82, wherein:
the multi-level electrical signal of the second channel is a fixed-pulse-width electrical signal, the acoustic audio component signal of the second channel is a fixed-pulse-width acoustic audio component signal, and the acoustic audio component signal of the first channel is a variable-pulse-width acoustic audio component signal generated from a variable-pulse-width electrical signal; and
the switching circuitry includes a set of switches for the first channel operative in response to assertion of the pulse width modulated signal to generate the variable-pulse-width electrical signal.

87. A digital audio system according to claim 82, further comprising a noise shaper operative to generate the first digital signal which is coarsely quantized from the digital signal.

88. A digital audio system according to claim 82, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

89. A digital audio system according to claim 82, wherein the digital signal is a first frequency component and each of the acoustic audio component signals is in a first frequency band associated with the first frequency component, the acoustic audio component signals in the first frequency band being additively combined to form a first frequency acoustic audio signal, the acoustic audio signal being generated by additively combining the first frequency acoustic audio signal in the first frequency band with a second frequency acoustic audio signal in a second frequency band associated with a second frequency component, a third digital signal carrying multi-bit values at a sampling rate being derived from the second frequency component and wherein the channels are channels in the first frequency band and the plurality of loudspeakers, plurality of low-pass filters, pulse width modulated signal, maximum-width-pulse signal, switching circuitry, PWM circuitry, level selector and switch control circuitry are a plurality of first loudspeakers, a plurality of first low-pass filters, first pulse width modulated signal, first maximum-width-pulse signal, first switching circuitry, first PWM circuitry, first level selector and first switch control circuitry respectively associated with the first frequency band, and further comprising:
a second loudspeaker associated with the second frequency band;
a second low-pass filter coupled to the second loudspeaker;
a band-separating filter operative to generate the first and second frequency components of a wide-band digital signal;
second switching circuitry operative in response to assertion of a second pulse width modulated signal to generate an electrical signal from which the second frequency acoustic audio signal is generated, the electrical signal being provided to the second low-pass filter; and
second PWM circuitry operative to generate the second pulse width modulated signal based on the third digital signal.

90. A digital audio system according to claim 89, wherein the third digital signal is the same as the second frequency component.

91. A digital audio system according to claim 89, wherein:
the third digital signal includes third and fourth digital sub-signals carrying respective least and most significant components of the multi-bit values carried by the third digital signal;
the electrical signal is a multi-level electrical signal from which the second frequency acoustic audio signal is generated;
second switching circuitry is operative in response to assertion of a third set of control signals to generate the multi-level electrical signal; and
second switch control circuitry includes a second level selector operative to assert each of the third set of control signals in response to the second pulse width modulated signal, a second maximum-width-pulse signal and the fourth digital sub-signal, the second maximum-width-pulse signal establishing the maximum permissible pulse duration in a sampling cycle for the second pulse width modulated signal.

92. A digital audio system according to claim 91, further comprising a noise shaper operative to generate the third digital signal which is coarsely quantized from the second frequency component.

93. A digital audio system according to claim 91, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

94. A digital audio system according to claim 91, wherein:
the multi-level electrical signal is one of a plurality of multi-level electrical signals in the second frequency band, each multi-level electrical signal in the second frequency band being generated from a corresponding one of a plurality of channels in the second frequency band;
the second frequency acoustic audio signal is generated by additively combining a plurality of acoustic audio component signals from the plurality of channels in the second frequency band, the acoustic audio component signal of each channel in the second frequency band being generated from a corresponding one of the multi-level electrical signals;
the second loudspeaker is one of a plurality of second loudspeakers each associated with a corresponding one of the channels in the second frequency band;
the second low-pass filter is one of a plurality of second low-pass filters each coupled to a corresponding one of the second loudspeakers;
the second switching circuitry includes a plurality of sets of switches, each set being associated with a corresponding one of the channels in the second frequency band, and the third set of control signals is one set of a plurality of third sets of control signals, each third set of control signals being associated with a corresponding channel in the second frequency band, each switch in the set of switches for each channel in the second frequency band being operative in response to assertion of a corresponding one of the third set of control signals for the corresponding channel in the second frequency band to provide one of a set of distinct levels of the multi-level electrical signal of the corresponding channel in the second frequency band;
each multi-level electrical signal generated from a corresponding one of the channels in the second frequency band is provided to its corresponding low-pass filter;
the second level selector is one of a plurality of second level selectors each being associated with a corresponding one of the channels in the second frequency band, the second level selector associated with a first one of the channels in the second frequency band being operative to assert each of the third set of control signals for the first channel in the second frequency band based on the second pulse width modulated signal, the second maximum-width-pulse signal and a fourth set of control signals for the first channel in the second frequency band, each of the other second level selectors being operative to assert control signals of the third set of control signals of the corresponding channel in the second frequency band in response to a fourth set of control signals for the corresponding channel in the second frequency band and the second maximum-width-pulse signal; and
the second switch control circuitry further includes an encoder operative to generate the fourth set of control signals for each channel in the second frequency band based on the fourth digital sub-signal.

95. A digital audio system according to claim 89, further comprising a noise shaper operative to generate the third digital signal which is coarsely quantized from the second frequency component.

96. A digital audio system according to claim 89, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

97. A digital audio system according to claim 89, wherein the first frequency band is a higher frequency band with more channels and the second frequency band is a lower frequency band with fewer channels.

98. A digital audio system according to claim 82, wherein the plurality of sets of switches are not coupled to a single power supply.

99. A digital audio system according to claim 82, the digital audio system being contained within a single enclosure.

100. A digital audio system according to claim 82, wherein the switches in each set of switches are arranged in a multiple H-bridge configuration and are operative to apply either (1) zero voltage level to both ends of a load connected to the switches, the load comprising a low-pass filter coupled to a loudspeaker, or (2) a positive or negative voltage level to one end of the load and a zero voltage level to the other end at any given time, such that current flowing through the load in one direction represents one positive voltage level, current flowing through the load in the reverse direction represents one negative voltage level, and no current flowing through the load represents a zero voltage level.

101. A digital audio system according to claim 82, wherein the switching circuitry is operative to select positive and negative voltages to generate the acoustic audio signal.

102. A digital audio system according to claim 82, wherein each of the levels in the set of distinct levels of each electrical signal is a corresponding ratio of a reference level and control of the volume of the acoustic audio signal is obtained by controlling the magnitude of the reference level.

103. Apparatus for controlling switching circuitry for generating an analog output from a digital signal the digital signal carrying multi-bit values at a sampling rate, the apparatus including a first digital signal derived from the digital signal, the first digital signal including first and second digital sub-signals carrying respective least and most significant components of the multi-bit values carried by the first digital signal, the analog output being generated by additively combining analog component outputs from first and second channels, the analog component output of the first channel being generated from an electrical signal of the first channel, the switching circuitry including a switching stage of the first channel operative in response to assertion of a pulse width modulated signal of the first channel to provide one of two predetermined levels of the electrical signal of the first channel, the analog component output of the second channel being generated from an electrical signal of the second channel, the switching circuitry further including a switching stage of the second channel operative in response to assertion of a pulse width modulated signal of the second channel to provide one of two predetermined levels of the electrical signal of the second channel, and the apparatus further comprising pulse width modulation (PWM) circuitry including
a PWM circuitry of the first channel operative to generate the pulse width modulated signal of the first channel, the pulse width modulated signal of the first channel being based on the first digital sub-signal and operative via the switching stage of the first channel to generate the electrical signal from which the analog component output of the first channel is generated and
a PWM circuitry of the second channel operative to generate the pulse width modulated signal of the second channel, the pulse width modulated signal of the second channel being based on the second digital sub-signal and operative via the switching stage of the second channel to generate the electrical signal from which the analog component output of the second channel is generated.

104. Apparatus according to claim 103, wherein the first digital signal is the same as the digital signal.

105. Apparatus according to claim 103, wherein:
the second channel is one of a plurality of high-level channels each generating a respective high-level electrical signal having two predetermined levels each of magnitude greater than or equal to the corresponding predetermined level of the first channel;
the analog output is generated by additively combining a plurality of analog component outputs from the first channel and the plurality of high-level channels, the analog component output from each high-level channel being generated from a corresponding one of the high-level electrical signals;
the switching stage of the second channel is one of a plurality of high-level switching stages, each high-level switching stage being associated with a corresponding one of the high-level channels, the pulse width modulated signal of the second channel being one of a plurality of pulse width modulated signals of the high-level channels, each pulse width modulated signal of the high-level channels being associated with a corresponding one of the high-level channels, each high-level switching stage being operative in response to assertion of a corresponding one of the pulse width modulated signals of the high-level channels to provide one of the two predetermined levels of the corresponding high-level electrical signal; and
the PWM circuitry of the second channel is one of a plurality of high-level PWM circuitry, each being associated with a corresponding one of the high-level channels, each high-level PWM circuitry being operative to assert the corresponding pulse width modulated signal of the high-level channel in response to a corresponding one of a plurality of first sets of control signals; and further comprising
an encoder operative to generate the first sets of control signals based on the second digital sub-signal.

106. Apparatus according to claim 105, wherein the control signals comprising the first sets of control signals generated by the encoder based on the second digital sub-signal are numbered consecutively starting from one and corresponding to the value of the second digital sub-signal such that all control signals having a number less than or equal to the value of the second digital sub-signal are turned on else turned off and the numbered control signals are interleaved among the different sets of first sets of control signals according to the numbers assigned to them.

107. Apparatus according to claim 103, wherein the two predetermined levels of each of the electrical signals are a corresponding pair of equal magnitude of positive and negative voltage levels, and the proportions of the positive and negative voltage level intervals of each electrical signal during a sampling cycle of the corresponding pulse width modulated signal corresponds to the pulse width of the corresponding pulse width modulated signal in the sampling cycle.

108. Apparatus according to claim 103, wherein the maximum pulse duration in a sampling cycle of the pulse width modulated signal of the first and second channels are the same.

109. Apparatus according to claim 103, wherein the electrical signal of the second channel is a higher magnitude electrical signal than the electrical signal of the first channel.

110. Apparatus according to claim 103, further comprising a noise shaper operative to generate the first digital signal which is coarsely quantized from the digital signal.

111. Apparatus according to claim 103, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

112. Apparatus according to claim 103, wherein the digital signal is a first frequency component and each of the analog component outputs is in a first frequency band associated with the first frequency component, the analog component outputs in the first frequency band being additively combined to form a first frequency analog output, the analog output being generated by additively combining the first frequency analog output in the first frequency band with a second frequency analog output in a second frequency band associated with a second frequency component, a third digital signal carrying multi-bit values at a sampling rate being derived from the second frequency component and wherein the channels are channels in the first frequency band and the pulse width modulated signal, switching circuitry and PWM circuitry are first pulse width modulated signal, first switching circuitry and first PWM circuitry respectively associated with the first frequency band, and further comprising:
a band-separating filter operative to generate the first and second frequency components of a wide-band digital signal;
second switching circuitry operative in response to assertion of a second pulse width modulated signal to provide one of the two predetermined levels of an electrical signal from which the second frequency analog output is generated; and
second pulse width modulation (PWM) circuitry operative to generate the second pulse width modulated signal based on the third digital signal.

113. Apparatus according to claim 112, wherein the third digital signal is the same as the second frequency component.

114. Apparatus according to claim 112, further comprising a noise shaper operative to generate the third digital signal which is coarsely quantized from the second frequency component.

115. Apparatus according to claim 112, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

116. Apparatus according to claim 112, wherein the first frequency band is a higher frequency band with more channels and the second frequency band is a lower frequency band with fewer channels.

117. Apparatus according to claim 112, wherein:
the third digital signal includes third and fourth digital sub-signals carrying respective least and most significant components of the multi-bit values carried by the third digital signal;
the second frequency analog output is generated by additively combining analog component outputs from first and second channels in the second frequency band;
the analog component output of the first channel in the second frequency band is generated from an electrical signal of the first channel in the second frequency band;
the analog component output of the second channel in the second frequency band is generated from an electrical signal of the second channel in the second frequency band;
the second switching circuitry includes a switching stage of the first channel in the second frequency band operative in response to assertion of a second pulse width modulated signal of the first channel in the second frequency band to provide one of the two predetermined levels of the electrical signal of the first channel in the second frequency band;
the second switching circuitry further includes a switching stage of the second channel in the second frequency band operative in response to assertion of a second pulse width modulated signal of the second channel in the second frequency band to provide one of the two predetermined levels of the electrical signal of the second channel in the second frequency band; and
the second PWM circuitry comprises (1) a PWM circuitry of the first channel in the second frequency band operative to generate the second pulse width modulated signal of the first channel in the second frequency band, the second pulse width modulated signal of the first channel in the second frequency band being based on the third digital sub-signal and operative via the switching stage of the first channel in the second frequency band to generate the electrical signal from which the analog component output of the first channel in the second frequency band is generated, and (2) a PWM circuitry of the second channel in the second frequency band operative to generate the second pulse width modulated signal of the second channel in the second frequency band, the second pulse width modulated signal of the second channel in the second frequency band being based on the fourth digital sub-signal and operative via the switching stage of the second channel in the second frequency band to generate the electrical signal from which the analog component output of the second channel in the second frequency band is generated.

118. Apparatus according to claim 117, wherein:
the second channel in the second frequency band is one of a plurality of high-level channels in the second frequency band;
the electrical signal of the second channel in the second frequency band is one of a plurality of high-level electrical signals in the second frequency band, each high-level electrical signal in the second frequency band being generated from a corresponding one of a plurality of high-level channels in the second frequency band;
the second frequency analog output is generated by additively combining a plurality of analog component outputs from the first channel and the plurality of high-level channels all in the second frequency band, the analog component output from each high-level channel in the second frequency band being generated from a corresponding one of the high-level electrical signals in the second frequency band;
the switching stage of the second channel in the second frequency band is one of a plurality of high-level switching stages in the second frequency band, each high-level switching stage in the second frequency band being associated with a corresponding one of the high-level channels in the second frequency band;
the second pulse width modulated signal of the second channel in the second frequency band is one of a plurality of second pulse width modulated signals of the high-level channels in the second frequency band, each second pulse width modulated signal of the high-level channels in the second frequency band being associated with a corresponding one of the high-level channels in the second frequency band, each high-level switching stage in the second frequency band being operative in response to assertion of a corresponding one of the second pulse width modulated signals of the high-level channels in the second frequency band to provide one of the two predetermined levels of the corresponding high-level electrical signal in the second frequency band; and
the PWM circuitry of the second channel in the second frequency band is one of a plurality of high-level PWM circuitry in the second frequency band, each being associated with a corresponding one of the high-level channels in the second frequency band, each high-level PWM circuitry in the second frequency band being operative to assert the corresponding second pulse width modulated signal of the high-level channel in the second frequency band in response to a corresponding one of a plurality of second sets of control signals; and further comprising
an encoder in the second frequency band operative to generate the second sets of control signals based on the fourth digital sub-signal.

119. Apparatus according to claim 117, further comprising a noise shaper operative to generate the third digital signal which is coarsely quantized from the second frequency component.

120. Apparatus according to claim 117, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

121. Apparatus according to claim 103, wherein the analog output is a physical output.

122. Apparatus according to claim 121, wherein the physical output is an acoustic output.

123. Apparatus according to claim 103, wherein each of the two predetermined levels of the electrical signal of a channel is a corresponding ratio of a reference level and control of the magnitude of the analog output is obtained by controlling the magnitude of the reference level.

124. Apparatus according to claim 103, wherein the switching stage of the channels are not coupled to a single power supply.

125. A digital audio system for generating an acoustic audio signal from a digital signal, the digital signal carrying multi-bit values at a sampling rate, the digital audio system including a first digital signal derived from the digital signal, the first digital signal including first and second digital sub-signals carrying respective least and most significant components of the multi-bit audio values carried by the first digital signal, the acoustic audio signal being generated by additively combining acoustic audio component signals from first and second channels, the acoustic audio component signal of the first channel being generated from an electrical signal of the first channel, the acoustic audio component signal of the second channel being generated from an electrical signal of the second channel, and the system further comprising:
a plurality of loudspeakers each associated with a corresponding one of the channels;
a plurality of low-pass filters each coupled to a corresponding one of the loudspeakers;
switching circuitry including a switching stage of the first channel operative in response to assertion of a pulse width modulated signal of the first channel to provide one of the two predetermined levels of the electrical signal of the first channel; the switching circuitry further including a switching stage of the second channel operative in response to assertion of a pulse width modulated signal of the second channel to provide one of the two predetermined levels of the electrical signal of the second channel, each electrical signal being provided to its corresponding low-pass filter; and pulse width modulation (PWM) circuitry including
a PWM circuitry of the first channel operative to generate the pulse width modulated signal of the first channel, the pulse width modulated signal of the first channel being based on the first digital sub-signal and operative via the switching stage of the first channel to generate the electrical signal from which the acoustic audio component signal of the first channel is generated and
a PWM circuitry of the second channel operative to generate the pulse width modulated signal of the second channel, the pulse width modulated signal of the second channel being based on the second digital sub-signal and operative via the switching stage of the second channel to generate the electrical signal from which the acoustic audio component signal of the second channel is generated.

126. A digital audio system according to claim 125, wherein the first digital signal is the same as the digital signal.

127. A digital audio system according to claim 125, wherein:
the second channel is one of a plurality of high-level channels each generating a respective high-level electrical signal having two predetermined levels each of magnitude greater than or equal to the corresponding predetermined level of the first channel;
the acoustic audio signal is generated by additively combining a plurality of acoustic audio component signals from the first channel and the plurality of high-level channels, the acoustic audio component signal from each high-level channel being generated from a corresponding one of the high-level electrical signals;
the switching stage of the second channel is one of a plurality of high-level switching stages, each high-level switching stage being associated with a corresponding one of the high-level channels, the pulse width modulated signal of the second channel being one of a plurality of pulse width modulated signals of the high-level channels, each pulse width modulated signal of the high-level channels being associated with a corresponding one of the high-level channels, each high-level switching stage being operative in response to assertion of a corresponding one of the pulse width modulated signals of the high-level channels to provide one of the two predetermined levels of the corresponding high-level electrical signal; and
the PWM circuitry of the second channel is one of a plurality of high-level PWM circuitry, each being associated with a corresponding one of the high-level channels, each high-level PWM circuitry being operative to assert the corresponding pulse width modulated signal of the high-level channel in response to a corresponding one of a plurality of first sets of control signals; and further comprising
an encoder operative to generate the first sets of control signals based on the second digital sub-signal.

128. A digital audio system according to claim 125, further comprising a noise shaper operative to generate the first digital signal which is coarsely quantized from the digital signal.

129. A digital audio system according to claim 125, wherein the digital signal carries multi-bit values at a first relatively low sampling rate, and further comprising:
an interpolator operative to perform interpolation based on the digital signal to obtain a second digital signal, the second digital signal carrying multi-bit values at a second sampling rate higher than the first sampling rate; and
a noise shaper operative to generate the first digital signal which is coarsely quantized from the second digital signal.

130. A digital audio system according to claim 125, wherein the digital signal is a first frequency component and each of the acoustic audio component signals is in a first frequency band associated with the first frequency component, the acoustic audio component signals in the first frequency band being additively combined to form a first frequency acoustic audio signal, the acoustic audio signal being generated by additively combining the first frequency acoustic audio signal in the first frequency band with a second frequency acoustic audio signal in a second frequency band associated with a second frequency component, a third digital signal carrying multi-bit values at a sampling rate being derived from the second frequency component and wherein the channels are channels in the first frequency band and the plurality of loudspeakers, plurality of low-pass filters, pulse width modulated signal, switching circuitry and PWM circuitry are a plurality of first loudspeakers, a plurality of first low-pass filters, first pulse width modulated signal, first switching circuitry and first PWM circuitry respectively associated with the first frequency band, and further comprising:
a second loudspeaker associated with the second frequency band;
a second low-pass filter coupled to the second loudspeaker;
a band-separating filter operative to generate the first and second frequency components of a wide-band digital signal;
second switching circuitry operative in response to assertion of a second pulse width modulated signal to provide one of the two predetermined levels of an electrical signal from which the second frequency acoustic audio signal is generated, the electrical signal being provided to the second low-pass filter; and
second pulse width modulation (PWM) circuitry operative to generate the second pulse width modulated signal based on the third digital signal.

131. A digital audio system according to claim 130, wherein the third digital signal is the same as the second frequency component.

132. A digital audio system according to claim 130, further comprising a noise shaper operative to generate the third digital signal which is coarsely quantized from the second frequency component.

133. A digital audio system according to claim 130, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

134. A digital audio system according to claim 130, wherein the first frequency band is a higher frequency band with more channels and the second frequency band is a lower frequency band with fewer channels.

135. A digital audio system according to claim 130, wherein:
the third digital signal includes third and fourth digital sub-signals carrying respective least and most significant components of the multi-bit values carried by the third digital signal;
the second frequency acoustic audio signal is generated by additively combining acoustic audio component signals from first and second channels in the second frequency band;
the acoustic audio component signal of the first channel in the second frequency band is generated from an electrical signal of the first channel in the second frequency band;
the acoustic audio component signal of the second channel in the second frequency band is generated from an electrical signal of the second channel in the second frequency band;
the second loudspeaker is one of a plurality of second loudspeakers each associated with a corresponding one of the channels in the second frequency band;
the second low-pass filter is one of a plurality of second low-pass filters each coupled to a corresponding one of the second loudspeakers;
the second switching circuitry includes a switching stage of the first channel in the second frequency band operative in response to assertion of a second pulse width modulated signal of the first channel in the second frequency band to provide one of the two predetermined levels of the electrical signal of the first channel in the second frequency band;
the second switching circuitry further includes a switching stage of the second channel in the second frequency band operative in response to assertion of a second pulse width modulated signal of the second channel in the second frequency band to provide one of the two predetermined levels of the electrical signal of the second channel in the second frequency band;
each electrical signal generated from a corresponding one of the channels in the second frequency band is provided to its corresponding second low-pass filter; and
the second PWM circuitry comprises (1) a PWM circuitry of the first channel in the second frequency band operative to generate the second pulse width modulated signal of the first channel in the second frequency band, the second pulse width modulated signal of the first channel in the second frequency band being based on the third digital sub-signal and operative via the switching stage of the first channel in the second frequency band to generate the electrical signal from which the acoustic audio component signal of the first channel in the second frequency band is generated, and (2) a PWM circuitry of the second channel in the second frequency band operative to generate the second pulse width modulated signal of the second channel in the second frequency band, the second pulse width modulated signal of the second channel in the second frequency band being based on the fourth digital sub-signal and operative via the switching stage of the second channel in the second frequency band to generate the electrical signal from which the acoustic audio component signal of the second channel in the second frequency band is generated.

136. A digital audio system according to claim 135, wherein:
the second channel in the second frequency band is one of a plurality of high-level channels in the second frequency band;
the electrical signal of the second channel in the second frequency band is one of a plurality of high-level electrical signals in the second frequency band, each high-level electrical signal in the second frequency band being generated from a corresponding one of a plurality of high-level channels in the second frequency band;
the second frequency acoustic audio signal is generated by additively combining a plurality of acoustic audio component signals from the first channel and the plurality of high-level channels all in the second frequency band, the acoustic audio component signal from each high-level channel in the second frequency band being generated from a corresponding one of the high-level electrical signals in the second frequency band;
the switching stage of the second channel in the second frequency band is one of a plurality of high-level switching stages in the second frequency band, each high-level switching stage in the second frequency band being associated with a corresponding one of the high-level channels in the second frequency band;
the second pulse width modulated signal of the second channel in the second frequency band is one of a plurality of second pulse width modulated signals of the high-level channels in the second frequency band, each second pulse width modulated signal of the high-level channels in the second frequency band being associated with a corresponding one of the high-level channels in the second frequency band, each high-level switching stage in the second frequency band being operative in response to assertion of a corresponding one of the second pulse width modulated signals of the high-level channels in the second frequency band to provide one of the two predetermined levels of the corresponding high-level electrical signal in the second frequency band; and
the PWM circuitry of the second channel in the second frequency band is one of a plurality of high-level PWM circuitry in the second frequency band, each being associated with a corresponding one of the high-level channels in the second frequency band, each high-level PWM circuitry in the second frequency band being operative to assert the corresponding second pulse width modulated signal of the high-level channel in the second frequency band in response to a corresponding one of a plurality of second sets of control signals, and further comprising
an encoder in the second frequency band operative to generate the second sets of control signals based on the fourth digital sub-signal.

137. A digital audio system according to claim 135, further comprising a noise shaper operative to generate the third digital signal which is coarsely quantized from the second frequency component.

138. A digital audio system according to claim 135, wherein the second frequency component carries multi-bit values at a third relatively low sampling rate, and further comprising:
an interpolator operative to perform interpolation based on the second frequency component to obtain a fourth digital signal, the fourth digital signal carrying multi-bit values at a fourth sampling rate higher than the third sampling rate; and
a noise shaper operative to generate the third digital signal which is coarsely quantized from the fourth digital signal.

139. A digital audio system according to claim 125, the digital audio system being contained within a single enclosure.

140. A digital audio system according to claim 125, wherein each of the two predetermined levels of the electrical signal of a channel is a corresponding ratio of a reference level and control of the volume of the acoustic audio signal is obtained by controlling the magnitude of the reference level.

141. A digital audio system according to claim 125, wherein the switching stage of the channels are not coupled to a single power supply.
